(19) United States
(12) Patent Application Publication
(10) Pub. No.: US 2011/0101431 A1
(43) Pub. Date: May 5, 2011

(54) SEMICONDUCTOR DEVICE AND METHOD OF MANUFACTURING SAME

(75) Inventors: Yosuke TAKEUCHI, Kanagawa (JP); Mikio Tsujiuchi, Kanagawa (JP); Tatsunori Murata, Kanagawa (JP)

(73) Assignee: RENESAS ELECTRONICS CORPORATION

(21) Appl. No.: 12/911,558

(22) Filed: Oct. 25, 2010

(30) Foreign Application Priority Data
Nov. 4, 2009 (JP) 2009-253084

(51) Int. Cl. H01L 29/82; H01L 21/8239

(52) U.S. Cl. 257/295; 438/3; 257/E21.645; 257/E29.323

(57) ABSTRACT

To provide a technology capable of improving the property of an MRAM in a semiconductor device containing the MRAM.

A plasma treatment is performed on the surface of an interlayer insulating film for which a wiring and a digit line are formed. Firstly, a semiconductor substrate is carried in a chamber, and a mixed gas that includes molecules containing nitrogen (ammonia gas) and inert molecules not containing nitrogen (hydrogen gas, helium, argon) is introduced into the chamber. On this occasion, the plasma treatment is performed by introducing the mixed gas under such a condition that the flow rate of the inert molecules not containing nitrogen is larger than that of the molecules containing nitrogen, and the mixed gas is turned into a plasma.

### CROSS-REFERENCE TO RELATED APPLICATION

The disclosure of Japanese Patent Application No. 2009-253084 filed on Nov. 4, 2009 including the specification, drawings and abstract is incorporated herein by reference in its entirety.

### BACKGROUND OF THE INVENTION

The present invention relates to a semiconductor device and the technology of manufacturing the same, particularly, to a technology that is effective when being applied to a semiconductor device containing an MRAM (Magnetic Random Access Memory) and the technology of manufacturing the same.

Japanese Patent Laid-Open No. 2006-165388 (Patent Document 1) describes a technology that suppresses an embedding failure or defective resolution in lithography caused by an affected layer formed over the surface of a low-permittivity film in a multilayer wiring process. Specifically, into a low-permittivity film over a silicon substrate, a lower layer barrier metal film and a lower layer metal film are embedded to form a lower layer wiring. Then, over the surface of the low-permittivity film, a damage layer having a prescribed thickness is formed by a plasma treatment using argon. Next, after removing the damage layer, the affected layer exposed on the surface of the low-permittivity film is modified. The modification of the affected layer is carried out by a plasma treatment using hydrogen or helium. It says that, after that, a first liner film is formed over the surface of the lower layer wiring and over the surface of the modified low-permittivity film.

Japanese Patent Laid-Open No. 2003-142580 (Patent Document 2) describes a technology for preventing the generation of a projection of a copper wiring layer and for preventing diffusion of copper. Specifically, it has, firstly, a process of exposing the surface of a copper wiring layer formed above a semiconductor substrate to the plasma of a gas selected from the group of ammonia gas, a mixed gas of nitrogen and hydrogen, CF4 gas, C2F6 gas, and NF3 gas. Then, it has a process of exposing the surface of the copper wiring layer to a gas atmosphere or a plasma selected from the group of ammonia gas, ethylenediamine gas, β-diketone gas, a mixed gas of ammonia gas and hydrocarbon-based gas, and a mixed gas of nitrogen gas and hydrocarbon-based gas. It says that, after that, a process of forming a copper diffusion-preventing insulating film over the copper wiring layer is included.

### SUMMARY OF THE INVENTION

Recently, as a new-generation nonvolatile memory device, an MRAM device attracts attention. The MRAM device is a nonvolatile memory device that carries out nonvolatile data storage using plural memory cells formed in a semiconductor integrated circuit and may randomly be accessed to each of the memory cells.

Generally, the memory cell of MRAM devices (magnetic memory element) includes a magneto resistance element of a spin valve structure, in which a fixed layer (pinned layer) containing a ferromagnetic layer having a fixed magnetization direction and a recording layer (free layer) containing a ferromagnetic layer having a variable magnetization direction according to an external magnetic field are disposed via a nonmagnetic layer. Since the magneto resistance element of the spin valve structure changes the electric resistance according to the change of the magnetization direction of the recording layer, the magneto resistance element may be operated as a memory by storing data according to the change of the electric resistance of the magneto resistance element.

In other words, in the memory cell of the MRAM device, an extremely thin tunnel insulating film is disposed between the fixed layer and the recording layer that contain a magnetic film. The structure having the tunnel insulating film laid between the fixed layer and the recording layer is referred to as a magnetic tunnel junction structure. The magnetic tunnel junction structure includes a magneto resistance element referred to as TMR (Tunneling Magneto Resistance).

In the magneto resistance element, the magnetization direction in the fixed layer is fixed in a definite direction. On the other hand, the magnetization direction in the recording layer is controllable by a magnetic field from the outside. When the magnetization direction of the fixed layer and the magnetization direction of the recording layer are in a parallel state pointing the same direction, a resistance value for current flowing between the fixed layer and the recording layer of the magneto resistance element becomes low. Inversely, when the magnetization direction of the fixed layer and the magnetization direction of the recording layer are in an antiparallel state pointing opposite directions, a resistance value for current flowing between the fixed layer and the recording layer of the magneto resistance element becomes high. Accordingly, it may be operated as a memory by reading the change of the resistance value while linking the parallel state or the antiparallel state of the magnetization direction with a digital value of “0” or “1.”

The above-described MRAM has a MISFET formed over a semiconductor substrate for selecting a memory cell and a magnetic memory element for storing information, wherein the MISFET and the magneto resistance element are connected with a multilayer wiring. In particular, the MISFET is formed over the semiconductor substrate, and the magneto resistance element is formed in a multilayer wiring layer. For example, the magneto resistance element includes a bottom electrode, a fixed layer formed over the bottom electrode, a tunnel insulating film formed over the fixed layer, a recording layer formed over the tunnel insulating film, and an upper electrode formed over the recording layer. The bottom electrode of the magneto resistance element is connected to the MISFET formed over the semiconductor substrate via the multilayer wiring, and the upper electrode of the magneto resistance element is connected with a bit line. Furthermore, below the bottom electrode of the magneto resistance element, a digit line that generates a magnetic field by causing an electric current to flow is formed for rewriting information stored in the magneto resistance element. In the MRAM having such a structure, the information stored in the magneto resistance element may be rewritten by changing the magnetization direction of the recording layer of the magneto resistance element by a resultant magnetic field occurring by causing a current to flow through the digit line and the bit line.

Here, the multilayer wiring constituting the MRAM is formed, for example, from a copper wiring. That is, in semiconductor devices, not limited to the MRAM, copper having a lower resistance value than aluminum has recently been used as a wiring material, and, as a technology for forming a wiring by processing copper, a wiring formation technology referred to as Damascene is examined. The Damascene method may broadly be classified into a Single-Damascene method and a Dual-Damascene method.

The Single-Damascene method is a method wherein, for example, a wiring trench is formed in an insulating film, and, after that, a copper film for forming a wiring is deposited over the insulating film and in the wiring trench, and, further, the copper film is polished by, for example, a CMP (Chemical Mechanical Polishing) so as to be left only in the wiring trench, to form an embedded wiring in the wiring trench.

The Dual-Damascene method is a method wherein a connection hole for connecting the wiring trench with the lower layer wiring is formed in an insulating film, and, after that, a copper film for forming a wiring is deposited over the insulating film, and in the wiring trench and the connection hole, and, further, the deposited copper film is polished by CMP so as to be left only in the wiring trench and the connection hole, to form an embedded wiring in the wiring trench and the connection hole.

By constituting the wiring of a semiconductor device from the copper wiring in this manner, the low resistivity of the wiring may be realized and the delay of signals transmitting through the wiring may be prevented. In particular, in semiconductor devices using the copper wiring having a low resistivity, in order to prevent further the delay of signals, a low-permittivity film having a lower permittivity than a silicon oxide film is used as an interlayer insulating film. That is, in order to suppress the delay of signals, it is useful to lower the resistivity of the wiring and to reduce the parasitic capacitance between wirings. Therefore, the use of the copper wiring having a low resistivity as a wiring, and the use of a low-permittivity film as the interlayer insulating film are examined.

The copper wiring is formed by the Damascene method, as described above, but copper atoms constituting the copper wiring have such nature that they move easily in silicon and silicon oxide. Hence, when a copper wiring is formed so as to be directly embedded in an interlayer insulating film constituted of a silicon oxide film, copper atoms diffuse easily into the semiconductor substrate over which the interlayer insulating film and MISFET are formed by a heat treatment etc. to deteriorate the electric property of the MISFET or the insulating property of the interlayer insulating film. Hence, usually, a barrier conductor film containing tantalum or tantalum nitride is formed over the side surface and bottom surface of the trench formed in the interlayer insulating film, and a copper film is formed so as to be embedded in the trench via the barrier conductor film. As the result of such constitution, copper atoms constituting the copper film are suppressed from the diffusion into the interlayer insulating film and the semiconductor substrate by the barrier conductor film. In the same manner, on the upper side of the copper wiring, a barrier insulating film (liner film) for preventing the diffusion of copper is formed. That is, on the upper side of the copper wiring, a barrier insulating film containing, for example, a silicon nitride film is formed to suppress the diffusion of copper atoms from the upper side of the copper wiring. At this time, from the standpoint of improving the adhesiveness of the surface of the copper wiring and the barrier insulating film, after the formation of the copper wiring, a plasma treatment by ammonia gas, or a mixed gas of ammonia gas and nitrogen gas is performed on the surface of the copper wiring, and, after that, the barrier insulating film is formed over the copper wiring.

Here, for the MRAM, the reduction of the rewriting current of the memory cell and the reduction of the variation of the rewriting current among memory cells are required in order to achieve the reduction of the power consumption and improvement of the performance. Specifically, in order to realize the reduction of the rewriting current of the memory cell, means shown below are considered. A first means is to shorten the interval between the magneto resistance element and the digit line. Such constitution may reduce the current flowing through the digit line without making small the magnetic field to be supplied to the magneto resistance element. That is, the current flowing through the digit line generates a magnetic field, wherein the magnetic field is greater when a greater current flows through the digit line and in a place nearer to the digit line. Accordingly, a short interval between the digit line and the magneto resistance element makes it possible to maintain the magnitude of the magnetic field necessary for the rewriting of the information stored in the magneto resistance element, even when a current flowing through the digit line is made small. As the result, the rewriting current (current flowing through the digit line) of the magneto resistance element may be reduced.

Subsequently, a second means for reducing the rewriting current of the memory cell is to devise the structure of the digit line. Specifically, by giving a cladding structure to the digit line, the magnetic field generated by the current flowing through the digit line may effectively be supplied to the magneto resistance element. The cladding here has such a structure that a barrier conductor film is formed over the side surface and the bottom surface of a trench formed in the interlayer insulating film and a copper film containing copper as the main constituent is formed over the barrier conductor film so as to be embedded into the trench, in the same manner as that in ordinary copper wiring, but is characterized in that the barrier conductor film is formed so as to contain a ferromagnetic film having a high magnetic permeability. When the barrier conductor film is constituted so as to contain the ferromagnetic film as described above, the generating magnetic field runs along the inside of the ferromagnetic film, and, as the result, the magnetic field, which usually appears on concentric circles having the center of the digit line (cladding), may intensively be concentrated to the magneto resistance element arranged on the upper side of the digit line, by the influence of the ferromagnetic film. This means that the magnetic field generated by causing a current to flow through the digit line may effectively be supplied to the magneto resistance element. That is, even when the rewriting current flowing through the digit line is reduced, by giving the cladding structure to the digit line, the magnitude of the magnetic field necessary for rewriting the information stored in the magneto resistance element may be maintained as the result of the increase in the utilization efficiency of the magnetic field.

As described above, in the MRAM, the reduction of the rewriting current may be achieved by shortening the interval between the magneto resistance element and the digit line, and giving the cladding structure to the digit line.

The digit line in the MRAM is also different in the point that it contains a ferromagnetic film in the barrier conductor film, from ordinary copper wiring, but, as to the method of forming the digit line, it is considered that a method similar to that of forming ordinary copper wirings may basically be applied. Accordingly, it is considered that, after the formation of the digit line in the MRAM, a plasma treatment by ammonia gas or a mixed gas of ammonia gas and nitrogen gas is performed on the surface of the digit line and, after that, the barrier insulating film is formed over the digit line, from the standpoint of improving the adhesiveness between the surface of the digit line and the barrier insulating film.

When the plasma treatment by the ammonia gas or mixed gas of ammonia gas and nitrogen gas is performed on the surface of the digit line, however, a problem shown below is caused. The problem will be described.

Firstly, above-described plasma treatment is performed in a chamber having an internal temperature of around 400° C. The heat treatment at this time enables copper atoms constituting the digit line (copper wiring) to move easily in the wiring, resulting in the easy occurrence of a deposit of a projection shape (hereinafter, referred to as a hillock) near grain boundaries. When the hillock occurs, it becomes necessary to secure a sufficient interval between the digit line and the magneto resistance element. Specifically, when the hillock occurs on the upper side of the digit line, consequently, the barrier insulating film is formed over the digit line with the hillock, and the interlayer insulating film is formed over the barrier insulating film. On this occasion, other copper wirings are formed in the same layer as the digit line, and, in order to form a via to be connected to these copper wirings, the surface of the interlayer insulating film formed over the barrier insulating film is flattened by the CMP (Chemical Mechanical Polishing) treatment. The CMP treatment exposes the hillock formed over the digit line, and, from the exposed hillock, the copper film solves to form a cavity defect in the digit line. Then, consequently, over the digit line with the cavity defect, a bottom electrode of the magneto resistance element is formed. On this occasion, the bottom electrode of the magneto resistance element is formed while reflecting the roughness of the surface of the digit line with the cavity defect, and, also to the tunnel insulating film to be disposed over the bottom electrode via the fixed layer, the roughness of the digit line is reflected. As the result, the uniformity of the tunnel insulating film deteriorates and the resistance value of the magneto resistance element varies, and the rewriting property and the reading property of the MRAM deteriorate.

From this reason, when performing a plasma treatment on the surface of the digit line using ammonia gas or a mixed gas of ammonia gas and nitrogen gas, it is necessary to give a larger thickness to the interlayer insulating film formed over the barrier insulating film, in consideration of the occurrence of the hillock on the digit line. That is, it is necessary to devise so that no hillock is exposed even when the CMP treatment is performed on the interlayer insulating film by giving a larger thickness to the interlayer insulating film. This means that the interval between the digit line and the magneto resistance element formed over the interlayer insulating film becomes larger, and that the reduction of the rewriting current flowing through the digit line may not be achieved.

Further, when the digit line is to be constituted from the cladding, there also occurs such problem that the variation of the rewriting current occurs among memory cells caused by the plasma treatment by ammonia gas or a mixed gas of ammonia gas and nitrogen gas. For example, when the ferromagnetic film contained in the barrier conductor film is formed from NiFe alloy as an example of the cladding structure, apart of the NiFe alloy is nitrided by the plasma treatment by ammonia gas or a mixed gas of ammonia gas and nitrogen gas, and, for example, NiFe alloy and NiFeN alloy coexist in the ferromagnetic film. The ratio of the formation of the NiFeN alloy is usually considered to be different for each of plural digit lines. Therefore, even when the same rewriting current is caused to flow through plural digit lines, different magnetic fields are supplied to each of memory cells because the ratio of the nitridation of the ferromagnetic film in the digit lines (cladding) varies. This means that different rewriting currents are caused to flow through each of digit lines in order to supply the magnetic field necessary for rewriting the information stored in respective memory cells. That is, the variation occurs in the rewriting current among memory cells.

As described above, the present inventors found that the direct application of the plasma treatment by ammonia gas or a mixed gas of ammonia gas and nitrogen gas, which is carried out after the formation of ordinary copper wiring for improving the adhesiveness between the copper wiring and the barrier insulating film, to the digit line having the cladding line structure brings about such problems that both the reduction of the rewriting current of the MRAM and the suppression of the variation in the rewriting current among memory cells become difficult.

The present invention has been made in view of the above circumstances and provides the technology capable of improving the properties of the MRAM in semiconductor devices containing the MRAM.

The other purposes and the new feature of the present invention will become clear from the description of the present specification and the accompanying drawings.

The following explains briefly the outline of a typical invention among the inventions disclosed in the present application.

A method of manufacturing a semiconductor device according to atypical embodiment includes the steps of (a) forming a MISFET over a semiconductor substrate, (b) forming a first interlayer insulating film above the MISFET, and (c) forming a first trench in the first interlayer insulating film. Further, it includes the steps of (d) forming a first barrier conductor film covering the side surface and the bottom surface of the first trench, forming a copper film containing copper as the main constituent over the first barrier conductor film so as to be embedded into the first trench, and thereby forming a first wiring in the first trench, and (e) performing a first plasma treatment on the surface of the first wiring and the surface of the first interlayer insulating film using a first gas that includes molecules containing nitrogen. Further, it includes the steps of (f), after the step (e), forming a first copper diffusion-preventing film for suppressing diffusion of copper over the first wiring and the first interlayer insulating film, (g) forming a second interlayer insulating film over the first copper diffusion-preventing film, and (h) forming a second trench in the second interlayer insulating film. Next, it includes the steps of (i) forming a second barrier conductor film containing a ferromagnetic film so as to cover the side surface and the bottom surface of the second trench, forming a copper film containing copper as the main constituent over the second barrier conductor film so as to be embedded into the second trench, and thereby forming a second wiring in the second trench, and (j) performing a second plasma treatment on the surface of the second wiring and the surface of the second interlayer insulating film under such conditions that a second gas which includes molecules containing nitrogen and inert molecules not containing nitrogen is used and the flow rate of the inert molecules not containing nitrogen is larger than that of the molecules containing nitrogen. Subsequently, it includes the steps of (k), after the step (j), forming a second copper diffusion-preventing film for suppressing diffusion of copper over the second wiring and the second interlayer insulating film, (l) forming a third interlayer insulating film over the second interlayer insulating film, and (m) forming a magneto resistance element over the third interlayer insulating film. Here, the second wiring is a wiring having a function of generating a part of the magnetic field for rewriting the information stored in the magneto resistance element by causing a current to flow through the second wiring.

Further, a method of manufacturing a semiconductor device according to atypical embodiment includes the steps of (a) forming a MISFET over a semiconductor substrate, (b) forming a first interlayer insulating film above the MISFET, and (c) forming a first trench in the first interlayer insulating film. Further, it includes the steps of (d) forming a first barrier conductor film covering the side surface and the bottom surface of the first trench, forming a copper film containing copper as the main constituent so as to be embedded into the first trench over the first barrier conductor film, and thereby forming a first wiring in the first trench, and (e) performing a first plasma treatment on the surface of the first wiring and the surface of the first interlayer insulating film using a first gas including molecules containing nitrogen. Further, it includes the steps of (f), after the step (e), forming a first copper diffusion-preventing film for suppressing diffusion of copper over the first wiring and the first interlayer insulating film, (g) forming a second interlayer insulating film over the first copper diffusion-preventing film, and (h) forming a second trench in the second interlayer insulating film. Next, it includes the step of (i) forming a second barrier conductor film containing a ferromagnetic film so as to cover the side surface and the bottom surface of the second trench, forming a copper film containing copper as the main constituent over the second barrier conductor film so as to be embedded into the second trench, and thereby forming a second wiring in the second trench. Subsequently, it includes the step of (j) performing a second plasma treatment on the surface of the second wiring and the surface of the second interlayer insulating film under such conditions that a second gas which includes molecules containing nitrogen and inert molecules not containing nitrogen is used and the flow rate of the inert molecules not containing nitrogen is larger than that of the molecules containing nitrogen. Further, it includes the steps of (k), after the step (j), forming a second copper diffusion-preventing film for suppressing diffusion of copper over the second wiring and the second interlayer insulating film, and (l) forming a magneto resistance element on the second copper diffusion-preventing film so as to directly contact the film. Here, the second wiring is a wiring having a function of generating a part of the magnetic field for rewriting the information stored in the magneto resistance element by causing a current to flow through the second wiring.

Further, a semiconductor device according to a typical embodiment is equipped with (a) an interlayer insulating film having a trench, the film formed above a semiconductor substrate, and (b) a magneto resistance element for storing information. Further, it is equipped with (c) a cladding line that has a function of generating apart of a magnetic field for rewriting the information stored in the magneto resistance element by causing a current to flow and is constituted so that a barrier conductor film containing a ferromagnetic film and a copper film containing copper as the main constituent are embedded in the trench formed in the interlayer insulating film. Further, it is equipped with (d) a copper diffusion-preventing film formed over the cladding line. Here, it is characterized in that the magneto resistance element is formed on the copper diffusion-preventing film so as to directly contact the film.

The following explains briefly the effect acquired by the typical invention among the inventions disclosed in the present application.

In semiconductor devices containing an MRAM, the properties of the MRAM may be improved.

### BRIEF DESCRIPTION OF THE DRAWINGS

FIG. 1 is a drawing showing a layout example of a semiconductor chip in embodiment 1.

FIG. 2 is a circuit block diagram showing the circuit configuration of an MRAM.

FIG. 3 is a cross-sectional view showing the structure of a semiconductor device in embodiment 1.

FIG. 4 is a drawing showing schematically a magnetic field generated by a current flowing through a digit line when the digit line is configured not to contain a ferromagnetic film.

FIG. 5 is a drawing showing schematically a magnetic field generated by a current flowing through a digit line when the digit line is configured to contain a ferromagnetic film.

FIG. 6 is a cross-sectional view illustrating the problem of a prior art.

FIG. 7 is a cross-sectional view illustrating the problem of a prior art, following FIG. 6.

FIG. 8 is a cross-sectional view illustrating the problem of a prior art, following FIG. 7.

FIG. 9 is a cross-sectional view illustrating the problem of a prior art, following FIG. 8.

FIG. 10 is a cross-sectional view illustrating the problem of a prior art, following FIG. 9.

FIG. 11 is a cross-sectional view illustrating the problem of a prior art, following FIG. 10.

FIG. 12 is a cross-sectional view illustrating the problem of a prior art, following FIG. 11.

FIG. 13 is a cross-sectional view illustrating the problem of a prior art, following FIG. 12.

FIG. 14 is a cross-sectional view showing the manufacturing process of a semiconductor device in the embodiment 1.

FIG. 15 is a cross-sectional view showing the manufacturing process of a semiconductor device, following FIG. 14.

FIG. 16 is a cross-sectional view showing the manufacturing process of a semiconductor device, following FIG. 15.

FIG. 17 is a cross-sectional view showing the manufacturing process of a semiconductor device, following FIG. 16.

FIG. 18 is a cross-sectional view showing the manufacturing process of a semiconductor device, following FIG. 17.

FIG. 19 is a cross-sectional view showing the manufacturing process of a semiconductor device, following FIG. 18.

FIG. 20 is a cross-sectional view showing the manufacturing process of a semiconductor device, following FIG. 19.

FIG. 21 is a cross-sectional view showing the manufacturing process of a semiconductor device, following FIG. 20.

FIG. 22 is a cross-sectional view showing the manufacturing process of a semiconductor device, following FIG. 21.

FIG. 23 is a cross-sectional view showing the manufacturing process of a semiconductor device, following FIG. 22.

FIG. 24 is a cross-sectional view showing the manufacturing process of a semiconductor device, following FIG. 23.

FIG. 25 is a cross-sectional view showing the manufacturing process of a semiconductor device, following FIG. 24.

FIG. 26 is a cross-sectional view showing the manufacturing process of a semiconductor device, following FIG. 25.

FIG. 27 is a cross-sectional view showing the manufacturing process of a semiconductor device, following FIG. 26.

FIG. 28 is a cross-sectional view showing the manufacturing process of a semiconductor device, following FIG. 27.

FIG. 29 is a cross-sectional view showing the manufacturing process of a semiconductor device, following FIG. 28.

FIG. 30 is a cross-sectional view showing the manufacturing process of a semiconductor device, following FIG. 29.

FIG. 31 is a cross-sectional view showing the manufacturing process of a semiconductor device, following FIG. 30.

FIG. 32 is a cross-sectional view showing the manufacturing process of a semiconductor device, following FIG. 31.

FIG. 33 is a cross-sectional view showing the manufacturing process of a semiconductor device, following FIG. 32.

FIG. 34 is a cross-sectional view showing the manufacturing process of a semiconductor device, following FIG. 33.

FIG. 35 is a cross-sectional view showing the manufacturing process of a semiconductor device, following FIG. 34.

FIG. 36 is a cross-sectional view showing the manufacturing process of a semiconductor device, following FIG. 35.

FIG. 37 is a cross-sectional view showing the manufacturing process of a semiconductor device, following FIG. 36.

FIG. 38 is a cross-sectional view showing the manufacturing process of a semiconductor device, following FIG. 37.

FIG. 39 is a cross-sectional view showing the manufacturing process of a semiconductor device, following FIG. 38.

FIG. 40 is a cross-sectional view showing the manufacturing process of a semiconductor device, following FIG. 39.

FIG. 41 is a cross-sectional view showing the manufacturing process of a semiconductor device, following FIG. 40.

FIG. 42 is a cross-sectional view showing the manufacturing process of a semiconductor device, following FIG. 41.

FIG. 43 is a cross-sectional view showing the manufacturing process of a semiconductor device, following FIG. 42.

FIG. 44 is a cross-sectional view showing the structure of a semiconductor device in embodiment 2.

### DETAILED DESCRIPTION OF THE PREFERRED EMBODIMENTS

The following embodiments will be explained, divided into plural sections or embodiments, if necessary for convenience. Except for the case where it shows clearly in particular, they are not mutually unrelated and one has relationships such as a modification, details, and supplementary explanation of some or entire of another.

In the following embodiments, when referring to the number of elements, etc. (including the number, a numeric value, an amount, a range, etc.), they may be not restricted to the specific number but may be greater or smaller than the specific number, except for the case where they are clearly specified in particular and where they are clearly restricted to a specific number theoretically.

Furthermore, in the following embodiments, it is needless to say that an element (including an element step etc.) is not necessarily indispensable, except for the case where it is clearly specified in particular and where it is considered to be clearly indispensable from a theoretical point of view, etc.

Similarly, in the following embodiments, when shape, position relationship, etc. of an element etc. is referred to, what resembles or is similar to the shape substantially shall be included, except for the case where it is clearly specified in particular and where it is considered to be clearly not right from a theoretical point of view. This statement also applies to the numeric value and range described above.

In all the drawings for explaining embodiments, the same symbol is attached to the same member, as a principle, and the repeated explanation thereof is omitted. In order to make a drawing intelligible, hatching may be attached even if it is a plan view.

### Embodiment 1

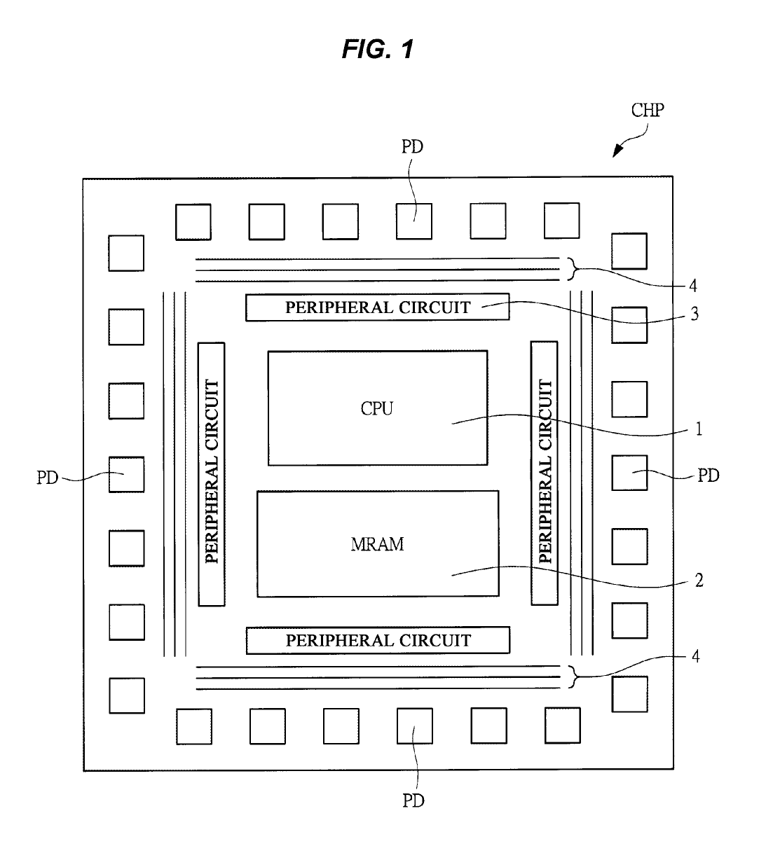

FIG. 1 is a plan view showing a layout example of a semiconductor chip in the Embodiment 1. As shown in FIG. 1, in a semiconductor chip CHP in the Embodiment 1, a CPU (Central Processing Unit, Microprocessor Unit) 1, an MRAM (Memory Unit) 2, a peripheral circuit 3, and a power line 4 are formed. In the peripheral part of the semiconductor chip CHP, a pad PD, which is an external terminal for input/output for connecting these circuits with an external circuit, is formed.

The CPU (circuit) 1 is also referred to as a central processing unit and corresponds to the heart of computer, etc. The CPU 1 reads out an instruction from a memory to decode it, and performs various calculations and controls based on it. For the CPU, high speed processing is required. Accordingly, for a MISFET (Metal Insulator Semiconductor Field Effect Transistor) constituting the CPU 1, relatively large current driving power is required among elements formed in the semiconductor chip CHP. That is, the MISFET is formed from a low voltage-resistant MISFET.

The MRAM (circuit) 2 is a memory capable of reading out storage information stored randomly, that is, stored as needed, and writing in storage information newly, which is also referred to as a memory capable of writing and reading on demand. As to the RAM as an IC memory, there are two kinds, for example, a DRAM (Dynamic RAM) using a dynamic circuit and an SRAM (Static RAM) using a static circuit. In the Embodiment 1, an MRAM being a next generation device is used. The MRAM 2 is a memory unit utilizing magnetism, and uses electronic spin as a memory element. The MRAM 2 has a structure similar to that of a DRAM, such that the capacitor in a DRAM is replaced by a magnetic tunnel junction element. The MRAM 2 is a nonvolatile memory because it uses a magnetized state for storage, and is characterized in that the storage state is held even after turning off the power, differing from DRAMs, etc. Furthermore, the MRAM 2 has a high-speed random access function (several nano seconds), as is the case for SRAMs. That is, the MRAM 2 is a memory element that functions as a nonvolatile memory and, in addition, has a high-speed random access function.

The peripheral circuit 3 is a circuit for constituting a system together with the CPU 1 and the MRAM 2, and contains, for example, a power source circuit, a clock circuit, a reset circuit, etc. The peripheral circuit 3 includes a digital circuit for processing digital signals and an analog circuit for processing analog signals. The analog circuit is a circuit that treats signals of temporally continuously changing voltage and current, that is, analog signals, and includes, for example, an amplification circuit, a conversion circuit, a modulation circuit, an oscillation circuit, a power source circuit, etc.

The power line 4 is a line for supplying voltage for causing the CPU 1, the MRAM 2 and the peripheral circuit 3 to operate, and includes a power source line and a ground line. The CPU 1, MRAM 2 and peripheral circuit 3 are coupled with the power line 4 directly or indirectly, so that they may operate by the power source supply from the power line 4.

The pad PD functions as an external connection terminal for performing input/output with a device (circuit) connected to the outside of the semiconductor chip CHP. It is configured such that input signals are input to the CPU 1 etc. formed in the semiconductor chip CHP via the pad PD, and that output signals from the CPU 1 is output to a device (circuit) connected to the outside of the semiconductor chip CHP via the pad PD.

In FIG. 1, plural pads PD are arranged along the peripheral part of the semiconductor chip CHP, and, inclose vicinity to the pads PD, the power line 4 is disposed. In the inside region of the power line 4, the CPU 1, MRAM 2 and peripheral circuit 3 are arranged. That is, the CPU 1, MRAM 2 and peripheral circuit 3 are arranged in the central region of the semiconductor chip CHP surrounded by the power line 4.

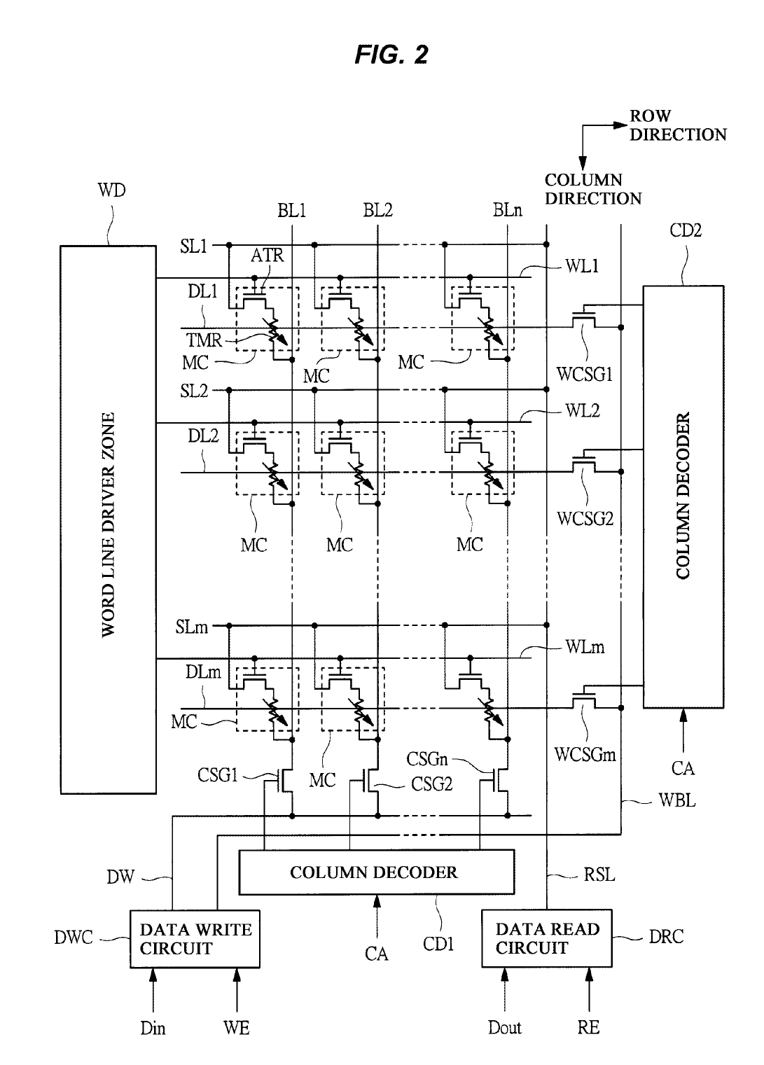

Next, the internal constitution of the MRAM 2 will be explained. FIG. 2 is a drawing showing the circuit configuration of the MRAM 2. In FIG. 2, the MRAM 2 is configured such that it accesses a specified memory cell randomly on the basis of a control signal and an address signal from the outside, and that, after that, performs the writing of input data Din and the reading of output data Dout for the accessed specified memory cell. The following explains the circuit configuration that will realize the function.

In FIG. 2, the MRAM 2 has plural memory cells MC arranged in a matrix shape having n rows in the row direction (lateral direction) and m columns in the column direction (longitudinal direction). That is, the MRAM 2 constitutes a memory cell array containing plural memory cells MC arranged in a row-column shape.

Along the row of the memory cell array, word lines WL1 to WLm and source lines SL1 to SLm are arranged so as to extend in parallel with each other. Furthermore, along the row of the memory cell array, digit lines DL1 to DLm are also arranged in parallel. On the other hand, along the column of the memory cell array, bit lines BL1 to BLn are arranged so as to extend in parallel with each other. That is, in the memory cell array constituting the MRAM 2, word lines WL1 to WLm, source lines SL1 to SLm and digit lines DL1 to DLm are arranged in parallel with each other in the lateral direction (row direction), and, on the other hand, bit lines BL1 to BLn are arranged in the longitudinal direction (column direction) orthogonal to the lateral direction.

At respective intersection points of the row-column shape of the memory cell array, respective memory cells MC are formed. Each memory cell MC has a magneto resistance element (magnetic tunnel junction element, magnetic memory element) TMR having a magnetic tunnel junction structure, and an access transistor ATR containing a MISFET (Metal Insulator Semiconductor Field Effect Transistor). The magneto resistance element TMR and the access transistor ATR are coupled so that the channel of the tunnel current flowing through the magneto resistance element TMR and the channel of the channel current flowing through the access transistor ATR are connected in series. Specifically, each memory cell MC has such a configuration that the drain region of the access transistor ATR is coupled to the magneto resistance element TMR.

In each of the memory cells MC, the source region of the access transistor ATR is coupled to a source line (any of source lines SL1 to SLm) constituting the memory cell array. The drain region of the access transistor ATR is coupled to one end of the magneto resistance element TMR, and the other end of the magneto resistance element TMR is coupled to a bit line (any of bit lines BL1 to BLn) constituting the memory cell array. Furthermore, the gate electrode of the access transistor ATR is coupled to a word line (any of word lines WL1 to WLm) constituting the memory cell array.

Subsequently, the MRAM 2 has a word line driver zone WD coupled to word lines WL1 to WLm. The word line driver zone WD has a function of activating selectively a word line (any of word lines WL1 to WLm), at the time of data reading (also referred to as “the time of data access”), corresponding to a specified memory cell MC to be a target of the data access, according to the result of row selection.

Furthermore, the MRAM 2 has a data line DW for transmitting read data, a write bit line WBL for transmitting write data, a read source line RSL, column decoders CD1 and CD2, a data write circuit DWC, and a data read circuit DRC.

The read source line RSL couples electrically each of the source lines SL1 to SLm with the data read circuit DRC. The data line DW is coupled to each of the bit lines BL1 to BLn via a selection transistor, and couples electrically bit lines BL1 to BLn with the data write circuit DWC. The write bit line WBL is coupled to each of the digit lines DL1 to DLm via a selection transistor, and couples electrically digit lines DL1 to DLm with the data write circuit DWC.

The data write circuit DWC has a function of applying a prescribed voltage to the data line DW and the write bit line WBL when write enable signal WE and input data Din are input from the outside. When read enable signal RE is input from the outside, the data read circuit DRC amplifies the voltage on the read source line RSL with a sense amplifier to compare it with the voltage value of a reference resistor (not shown). It has a function of outputting output data Dout on the basis of the comparison result.

The MRAM 2 has the selection transistor corresponding to each of the columns of the memory cell array, and respective gate electrodes of the selection transistor are shown by gate electrodes CSG1 to CSGn. Similarly, the MRAM 2 has the selection transistor corresponding to each of the rows of the memory cell array, and respective gate electrodes of the selection transistor are shown by gate electrodes WCSG1 to WCSGm.

The column decoder CD1, as the result of decoding the column address CA, has a function of activating selectively gate electrodes CSG1 to CSGn at each of the date write and the data read on the basis of the result. The activated gate electrode (any of CSG1 to CSGn) has a function of coupling electrically the data line DW with a corresponding bit line (any of bit lines BL1 to BLn).

Similarly, the column decoder CD2, as the result of decoding the column address CA, has a function of activating selectively gate electrodes WCSG1 to WCSGm on the basis of the result. The activated gate electrode (any of WCSG1 to WCSGm) has a function of coupling electrically the write bit line WBL with a corresponding digit line (any of digit lines DL1 to DLm).

The circuit of the MRAM 2 in the Embodiment 1 is constituted as described above, and the following explains the structure of the memory cell of the MRAM 2.

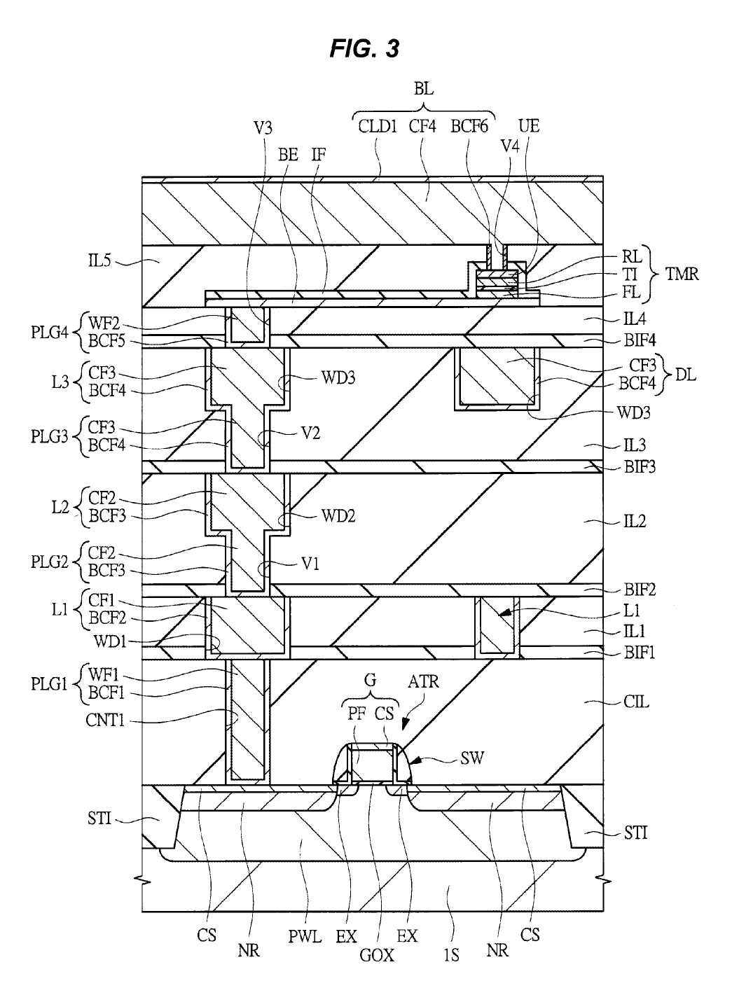

FIG. 3 is a cross-sectional view showing the structure of the memory cell constituting the MRAM 2. In FIG. 3, the memory cell constituting the MRAM 2 includes an access transistor ATR formed over the semiconductor substrate 1S, a multilayer wiring formed on the upper side of the access transistor ATR, and a magneto resistance element TMR formed in the wiring layer in which the multilayer wiring is formed.

Firstly, the structure of the access transistor ATR formed over the semiconductor substrate 1S is explained. As shown in FIG. 3, on the surface (principal surface) of the semiconductor substrate 1S, plural element isolation regions STI are formed, and, in an active region partitioned by these element isolation regions STI, a p-type well PWL is formed. The p-type well PWL is a p-type semiconductor region formed by introducing a p-type impurity such as boron into the semiconductor substrate 1S.

Over the p-type well PWL, a gate insulating film GOX is formed, and, over the gate insulating film GOX, a gate electrode G is formed. The gate insulating film GOX is formed from, for example, a silicon oxide film, and the gate electrode G is formed from, for example, a laminated film of a polysilicon film. PF and a cobalt silicide film CS. The cobalt silicide film CS is formed for reducing the gate resistance of the gate electrode G.

On the side walls on both sides of the gate electrode G, a sidewall SW is formed, and the sidewall SW is formed from, for example, a laminated film of a silicon oxide film and a silicon nitride film. However, the structure of the sidewall SW is not limited to it, but the sidewall may also be formed from a single layer film of a silicon oxide film or a single layer film of a silicon nitride film.

In the semiconductor substrate 1S under the sidewall SW, a shallow n-type impurity diffusion region EX is formed as a semiconductor region. Outside the shallow n-type impurity diffusion region EX, a deep n-type impurity diffusion region NR is formed, and, on the deep n-type impurity diffusion region NR, a cobalt silicide film CS is formed.

The sidewall SW is formed for giving an LDD structure to the source region and the drain region being the semiconductor region of the access transistor ATR. That is, the source region and the drain region of the access transistor are formed from the shallow n-type impurity diffusion region EX, the deep n-type impurity diffusion region NR and the cobalt silicide film CS. At this time, the shallow n-type impurity diffusion region EX has an impurity concentration lower than that of the deep n-type impurity diffusion region NR. Accordingly, by using the source region and the drain region under the sidewall SW as the shallow n-type impurity diffusion region EX with a low concentration, the electric field concentration under the edge portion of the gate electrode G may be suppressed.

As described above, the access transistor ATR is formed, and, on the upper side of the access transistor ATR, the multilayer wiring is formed. The structure of the multilayer wiring is explained below. As shown in FIG. 3, over the semiconductor substrate 1S for which the access transistor ATR is formed, the contact interlayer insulating film. CIL is formed so as to cover the access transistor ATR. The contact interlayer insulating film CIL is formed from, for example, a laminated film of an ozone TEOS film formed by a thermal CVD method using ozone and TEOS (Tetra Ethyl Ortho Silicate) as raw materials, and a plasma TEOS film formed by a plasma CVD method using TEOS as a raw material, which is provided over the ozone TEOS film. While passing through the contact interlayer insulating film CIL, a plug PLG1 that reaches the drain region of the access transistor ATR is formed. The plug PLG1 is formed, for example, by embedding a barrier conductor film BCF1 containing a titanium/titanium nitride film (hereinafter, titanium/titanium nitride film indicates a film formed by titanium and titanium nitride provided over the titanium), and a tungsten film WF1 formed over the barrier conductor film BCF1 into a contact hole CNT1. The titanium/titanium nitride film is a film provided for preventing the diffusion of tungsten constituting the tungsten film into silicon, and for preventing fluorine attack given to the contact interlayer insulating film CIL and the semiconductor substrate 1S to give damage in a CVD method in which WF6 (tungsten fluoride) is subjected to a reduction treatment when the tungsten film is constituted. Meanwhile, the contact interlayer insulating film CIL may be formed from any of a silicon oxide film (SiO2 film), a SiOF film and a silicon nitride film.

Subsequently, over the contact interlayer insulating film CIL, a wiring L1 is formed as a first wiring layer. Specifically, the wiring L1 is formed so as to be embedded into a barrier insulating film. BIF1 formed over the contact interlayer insulating film CIL in which a plug PLG1 is formed, and an interlayer insulating film IL1. That is, the wiring L1 is formed by embedding a barrier conductor film. BCF2 and a film containing copper as the main constituent (hereinafter, mentioned as a copper film CF1) into a wiring trench WD1 in which the plug PLG1 is exposed at the bottom portion after passing through the barrier insulating film BIF1 and the interlayer insulating film IL1. That is, the wiring L1 is formed from the barrier conductor film BCF2 formed so as to cover the side surface and bottom surface of the wiring trench WD1, and a copper film CF1 formed so as to be embedded into the wiring trench WD1 over the barrier conductor film BCF2.

The reason why a copper film is formed not directly in the wiring trench WD1 formed in the barrier insulating film BIF1 and the interlayer insulating film IL1 but the barrier conductor film BCF1 is formed is to prevent the diffusion of copper constituting the copper film CF1 into silicon constituting the semiconductor substrate 1S by a heat treatment etc. That is, copper atoms have a relatively large diffusion constant relative to silicon, and diffuse easily into silicon. On this occasion, for the semiconductor substrate 1S, such a semiconductor element as the access transistor ATR is formed, and copper atoms diffusing into formation regions thereof bring about the property deterioration of the semiconductor element represented by withstand voltage failure etc. In order to prevent this, the barrier conductor film BCF2 is provided so that copper atoms do not diffuse from the copper film CF1 constituting the wiring L1. That is, it is understood that the barrier conductor film BCF2 is a film having a function of preventing the diffusion of copper atoms.

The barrier conductor film BCF2 is formed from, for example, a film containing any of a tantalum film, titanium film, ruthenium film, tungsten film, manganese film, and a nitride film or a nitriding silicide film thereof. Furthermore, the copper film CF1 is formed from a film containing copper as the main constituent, not limited to a pure copper film. Specifically, the copper film CF1 is formed from copper (Cu) or a copper alloy (alloy of copper (Cu) and aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), indium (In), lanthanoid-based metal, actinoid-based metal, or the like).

The barrier insulating film BIF1, too, is a film provided for preventing the diffusion of copper atoms constituting the wiring L1 into the inside of the interlayer insulating film IL1 and the semiconductor substrate 1S, as is the case for the barrier conductor film BCF2. The barrier insulating film BIF1 is formed from, for example, a film containing any of a SiN film (silicon nitride film), a SiON film (silicon oxide nitride film), a SiC film (silicon carbide film), a SiCN film (silicon carbide nitride film), and a SiCO film. Furthermore, the interlayer insulating film is formed from a silicon oxide film or a low-permittivity film having a lower permittivity than a silicon oxide film. Specifically, the interlayer insulating film IL1 contains, for example, a SiOC film, a HSQ (hydrogen silsesquioxane, a silicon oxide film that is formed by a coating process and has a Si—H bond, or a hydrogen-containing silsesquioxane) film or a MSQ (methyl silsesquioxane, a silicon oxide film that is formed by a coating process and has a Si—C bond, or a carbon-containing silsesquioxane) film, a TEOS film, a silicon oxide film, or a SiOF film.

Over the interlayer insulating film IL1 for which the wiring L1 is formed, a barrier insulating film BIF2 is formed, and, over the barrier insulating film BIF2, an interlayer insulating film IL2 is formed. The barrier insulating film BIF2 contains the material similar to that of the barrier insulating film BIF1 described above, and the interlayer insulating film IL2 is formed from the material similar to that of the interlayer insulating film IL1.

So as to pass through the barrier insulating film BIF2 and the interlayer insulating film IL2, a wiring trench WD2 and a via hole V1 are formed. Further, so as to be embedded into the via hole V1, a plug PLG2 is formed, and, so as to be embedded into the wiring trench WD2, a wiring L2 is formed. Accordingly, the wiring L2 is electrically coupled to the wiring L1 via the plug PLG2. The wiring L2 is formed from a barrier conductor film BCF3 formed so as to cover the side surface and the bottom surface of the wiring trench WD2, and a copper film CF2 formed so as to be embedded into the wiring trench WD2 over the barrier conductor film BCF3. In a similar manner, the plug PLG2 is formed from the barrier conductor film BCF3 formed so as to cover the side surface and the bottom surface of the via hole V1, and the copper film CF2 formed so as to be embedded into the via hole V1 over the barrier conductor film BCF3.

Meanwhile, the barrier conductor film BCF3 is formed from a material similar to that of the barrier conductor film BCF2, and the copper film CF2 is also formed from a material similar to that of the copper film CF1.

Subsequently, over the interlayer insulating film IL2 for which the wiring L2 is formed, a barrier insulating film BIF3 is formed, and, over the barrier insulating film BIF3, an interlayer insulating film IL3 is formed. The barrier insulating film BIF3 is formed from a material similar to that of the barrier insulating film BIF1 and the barrier insulating film BIF2 described above, and the interlayer insulating film IL3 is formed from a material similar to that of the interlayer insulating film IL2.

So as to pass through the barrier insulating film BIF3 and the interlayer insulating film IL3, a wiring trench WD3 and a via hole V2 are formed. Further, so as to be embedded into the via hole V2, a plug PLG3 is formed, and, so as to be embedded into the wiring trench WD3, a wiring L3 is formed. Accordingly, the wiring L3 is electrically coupled to the wiring L2 via the plug PLG3. The wiring L3 is formed from a barrier conductor film BCF4 formed so as to cover the side surface and the bottom surface of the wiring trench WD3, and a copper film CF3 formed so as to be embedded into the wiring trench WD3 over the barrier conductor film BCF4. In a similar manner, the plug PLG3 is formed from a barrier conductor film BCF4 formed so as to cover the side surface and the bottom surface of the via hole V2, and the copper film CF3 formed so as to be embedded into the via hole V2 over the barrier conductor film BCF4.

For the interlayer insulating film IL3, a digit line DL is formed in the same layer as the wiring L3. The digit line DL is also formed from the barrier conductor film. BCF4 formed so as to cover the side surface and the bottom surface of the wiring trench WD3, and the copper film CF3 formed so as to be embedded into the wiring trench WD3 over the barrier conductor film BCF4.

Here, the structure of the barrier conductor film BCF4 constituting a part of the wiring L3 and a part of the digit line DL differs from that of the barrier conductor film BCF2 and the barrier conductor film BCF3 constituting a part of the wiring L2 and a part of the wiring L1 described above. That is, the barrier conductor film BCF4 is constituted so as to contain a ferromagnetic film having a high permeability. For example, the barrier conductor film BCF4 is constituted from a laminated film including a tantalum nitride film, a first tantalum film formed over the tantalum nitride film, a ferromagnetic film formed over the first tantalum film, and a second tantalum film formed over the ferromagnetic film. However, films constituting the barrier conductor film BCF4 other than the ferromagnetic film may occasionally be formed from films containing any of a tantalum film, a titanium film, a ruthenium film, a tungsten film, a manganese film, and a nitride film or a nitriding silicide film thereof.

The ferromagnetic film is formed so as to contain any of, for example, a nickel film, an iron film, a cobalt film, and an alloy film containing an alloy of these films, or a film formed by adding any element of chromium, molybdenum, aluminum, silicon, zirconium and boron to the nickel film, the iron film, the cobalt film or the alloy film.

Next, over the interlayer insulating film IL3 for which the wiring L3 and the digit line DL are formed, a barrier insulating film BIF4 is formed, and, over the barrier insulating film BIF4, an interlayer insulating film IL4 is formed. The barrier insulating film BIF4 contains a material similar to that of the barrier insulating film BIF1 and the barrier insulating film BIF2 described above, and the interlayer insulating film IL4 is formed from a material similar to that of the interlayer insulating film IL2 and the interlayer insulating film IL3 described above.

Then, so as to pass through the barrier insulating film BIF4 and the interlayer insulating film IL4, a via hole V3 is formed. So as to be embedded into the via hole V3, a plug PLG4 is formed. Accordingly, the plug PLG4 is electrically coupled to the wiring L3. The plug PLG4 is formed from a barrier conductor film BCF5 formed so as to cover the side surface and the bottom surface of the via hole V3, and a tungsten film WF2 formed so as to be embedded into the via hole V3 over the barrier conductor film BCF5. Meanwhile, it may be formed from a copper film in place of the tungsten film WF2. On this occasion, the barrier conductor film. BCF5 is formed from, for example, a material similar to that of the barrier conductor film BCF2 and the barrier conductor film BCF3.

Subsequently, over the interlayer insulating film IL4 for which the plug PLG4 is formed, a magneto resistance element TMR is formed. The structure of the magneto resistance element TMR is explained below. As shown in FIG. 3, firstly, a bottom electrode BE is formed so as to be connected with the plug PLG4 formed in the interlayer insulating film IL4 and to extend up to over the digit line DL. The bottom electrode BE is formed from, for example, a film containing a tantalum film, a tantalum nitride film, a titanium film, a titanium nitride film, a ruthenium film, a nickel iron chromium (NiFeCr) film, or a laminated film thereof.

Over the bottom electrode BE, the magneto resistance element TMR is formed. Specifically, the magneto resistance element TMR is formed from a fixed layer FL formed over the bottom electrode BE, a tunnel insulating film TI formed over the fixed layer FL, and a recording layer RL formed over the tunnel insulating film TI. On this occasion, the fixed layer FL, the tunnel insulating film TI and the recording layer RL constituting the magneto resistance element TMR are formed above the digit line DL, wherein the magneto resistance element TMR and the digit line DL have layout relationship of overlapping with each other in a planar view.

The fixed layer FL is a layer having a fixed magnetization direction, and is constituted so that the magnetization direction is not changed by an exterior magnetic field. Specifically, the fixed layer FL is formed from, for example, a first nonmagnetic layer to be a seed layer, an antiferromagnetic layer formed over the first nonmagnetic layer, a first ferromagnetic layer formed over the antiferromagnetic layer, a second nonmagnetic layer formed over the first ferromagnetic layer, and a second ferromagnetic layer formed over the second nonmagnetic layer. Such constitution makes it possible to fix the magnetization direction of the second ferromagnetic layer.

For example, the nonmagnetic layer is a layer having a function of improving crystalline orientation properties, and is formed from a metal film such as a tantalum film, a ruthenium film, an aluminum film, a magnesium film or the like. On the other hand, the antiferromagnetic layer is formed from, for example, a platinum manganese (PtMn) film, an iridium manganese (IrMn) film or the like. Furthermore, the ferromagnetic layer is formed, for example, so as to contain any of a nickel film, an iron film, a cobalt film and an alloy film containing an alloy of these films, and a film formed by adding any element of chromium, molybdenum, aluminum, silicon, zirconium and boron to the nickel film, the iron film, the cobalt film or the alloy films.

Subsequently, the tunnel insulating film TI is a film for separating the fixed layer FL from the recording layer RL, and is controlled to such a thickness that allows a tunneling current to flow between the fixed layer FL and the recording layer RL. The tunnel insulating film TI is formed from, for example, a metal oxide film such as an aluminum oxide film or a magnesium oxide film.

On the other hand, the recording layer RL is a film constituted so that the magnetization direction is variable by an exterior magnetic field, and is formed from a ferromagnetic film. For example, the recording layer RL is formed so as to contain any of a nickel film, an iron film, a cobalt film and an alloy film containing an alloy of these films, and a film formed by adding any element of chromium, molybdenum, aluminum, silicon, zirconium and boron to the nickel film, the iron film, the cobalt film or the alloy films.

Subsequently, over the recording layer RL, an upper electrode UE is formed. The upper electrode UE is formed from a nonmagnetic layer, and is formed from, for example, a tantalum film or a ruthenium film. As described above, the magneto resistance element TMR is formed.

So as to cover the magneto resistance element TMR, an insulating film IF and an interlayer insulating film IL5 are formed. So as to pass through the insulating film IF and the interlayer insulating film IL5 to reach the upper electrode UE, a via hole V4 is formed. On the side surface of the via hole V4, a barrier conductor film BCF6 containing a ferromagnetic film is formed, and, further, a copper film CF4 is formed so as to be embedded into the via hole V4 over the barrier conductor film BCF6. The copper film CF4 embedded into the via hole V4 is also formed in a wiring trench formed in the interlayer insulating film IL5, and, over the copper film CF4, a clad film CLD1 is formed. As described above, the bit line BL containing the barrier conductor film BCF6, the copper film CF4 and the clad film CLD1 is formed.

Here, the barrier conductor film BCF6 and the clad film CLD1 constituting the bit line BL are constituted so as to contain a ferromagnetic film. The ferromagnetic film is formed so as to contain any of, for example, a nickel film, an iron film, a cobalt film and an alloy film containing an alloy of these films, and films formed by adding any element of chromium, molybdenum, aluminum, silicon, zirconium and boron to the nickel film, the iron film, the cobalt film or the alloy film. The copper film CF4 is formed from a film having the quality of the material similar to that of the copper films CF1 to CF3. As described above, a memory cell including the access transistor ATR, the multilayer wiring and the magneto resistance element TMR is constituted. Here, the drain region of the access transistor ATR is electrically coupled to the bottom electrode BE of the magneto resistance element TMR (fixed layer FL) via the wirings L1 to L3 constituting the multilayer wiring. Further, the upper electrode UE of the magneto resistance element TMR (recording layer RL) is electrically coupled to the bit line BL. Furthermore, below the magneto resistance element TMR, the digit line DL is disposed. This couples the access transistor ATR with the magneto resistance element TMR in series. As described above, the memory cell of the MRAM in the Embodiment 1 is constituted.

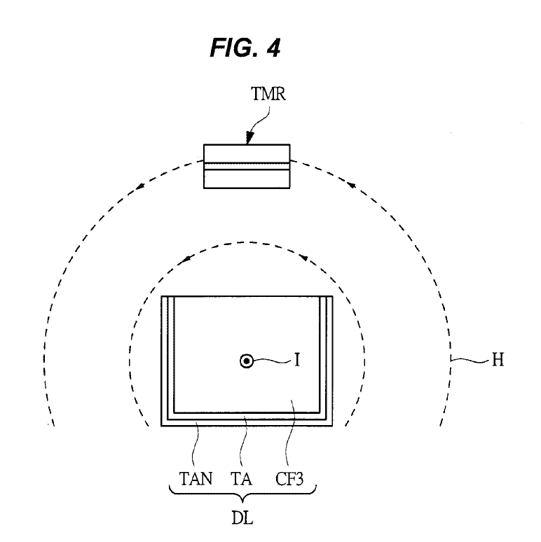

In the MRAM of the Embodiment 1, the digit line DL is formed from a film containing a ferromagnetic film. Next, advantages given by the constitution will be explained while referring to the drawings. FIG. 4 shows an instance where the digit line DL is constituted so as not to contain a ferromagnetic film. For example, in FIG. 4, the digit line DL is formed from a laminated film of a tantalum nitride film TAN, a tantalum film TA and the copper film CF3. Further, above the digit line DL, the magneto resistance element TMR is disposed. When a current I (a part of the rewriting current) is caused to flow through the digit line DL in this state, the current I generates a magnetic field H. The magnetic field H is generated on concentric circles so as to surround the circumference of the current I.

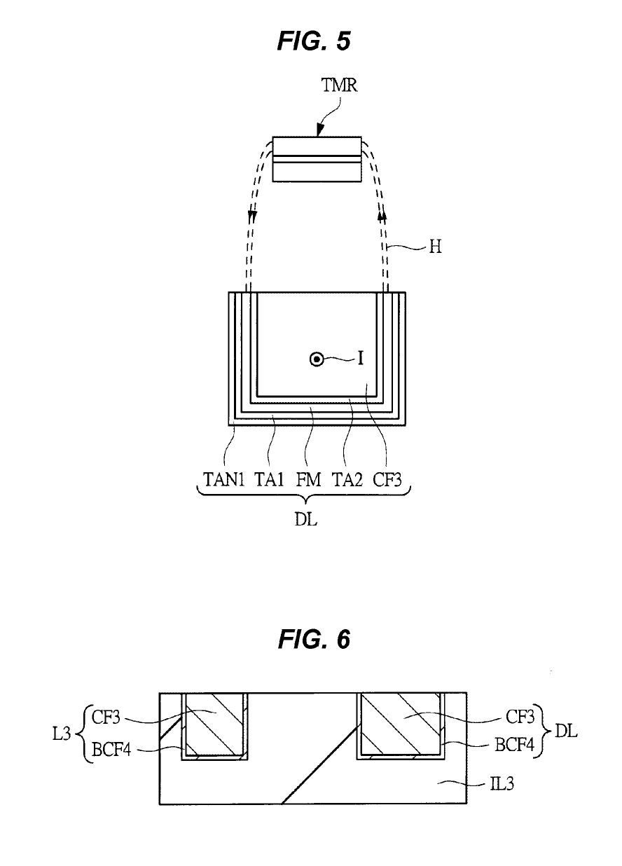

On the other hand, FIG. 5 shows an instance where the digit line DL is formed so as to contain a ferromagnetic film. The wiring constituted so that the digit line DL contains a ferromagnetic film as described above is occasionally referred to as a cladding line (cladding line structure). On this occasion, for example, the digit line DL contains a tantalum nitride film TAN1, a tantalum film TA1, a ferromagnetic film FM, an tantalum film TA2 and the copper film. CF3. Here, the reason why the tantalum nitride film TAN1 and the tantalum film TA1 are provided between the ferromagnetic film FM and the wiring trench is to prevent the oxidization of the ferromagnetic film FM caused by the direct contact of the ferromagnetic film FM with a silicon oxide film constituting the interlayer insulating film. On the other hand, the reason why the tantalum film TA2 is formed between the ferromagnetic film FM and the copper film CF3 is to prevent the diffusion of atoms constituting the ferromagnetic film FM into the copper film CF3.

When the current I is caused to flow through the digit line DL constituted as described above, the magnetic field H is not generated on concentric circles, but passes through the inside of a ferromagnetic film constituting the digit line DL. That is, the magnetic field H generated by the current I passes through the inside of the ferromagnetic film having a high permeability, and, therefore, the magnetic field H intensively concentrates to the magneto resistance element TMR disposed above the digit line DL. That is, when the digit line DL is constituted so as to contain a ferromagnetic film, the generated magnetic field H passes through along the inside of the ferromagnetic film, and, consequently, the magnetic field, which usually appears on concentric circles with the digit line DL (cladding line) as the center, may be intensively concentrated to the magneto resistance element TMR disposed on the upper side of the digit line DL by the influence of the ferromagnetic film. This means that the magnetic field H generated by causing the current I to flow through the digit line DL may effectively be supplied to the magneto resistance element TMR. That is, by giving the cladding line structure to the digit line DL, the utilization efficiency of the magnetic field H increases, and, as the result, the magnitude of the magnetic field necessary for rewriting the information stored in the magneto resistance element TMR may be maintained even when the current I flowing through the digit line DL is reduced. As described above, the MRAM according to the Embodiment 1 has such an advantage that the magnetization direction of the recording layer RL of the magneto resistance element TMR may be changed with a small rewriting current by giving the clad structure to the digit line DL.

Here, actually, the magnetic field for changing the magnetization direction of the recording layer RL of the magneto resistance element TMR uses a resultant magnetic field of a magnetic field generated by causing a current to flow through the digit line DL, and a magnetic field generated by causing a current to flow through the bit line BL. The reason is that the constitution that changes the magnetization direction of the recording layer RL only with the magnetic field generated by a current flowing through the digit line DL brings about the rewriting in all the memory cells disposed over the digit line DL. Therefore, such a constitution is given that a current is caused to flow through both the digit line DL and the bit line BL, and that the only the resultant magnetic field of a magnetic field generated by the current flowing through the digit line DL and a magnetic field generated by the current flowing through the bit line BL changes the magnetization direction of the recording layer RL, so as to be capable of rewriting only the memory cell arranged at the intersect region of the digit line DL and the bit line BL. Accordingly, the bit line BL also has the clad structure so that the magnetic field generated by causing a current to flow through the bit line BL may effectively be collected to the recording layer RL. That is, in the Embodiment 1, it is possible to achieve the reduction of the rewriting current by giving the cladding line structure to both the digit line DL and the bit line BL.

Subsequently, the operation of the MRAM will be explained while referring to FIG. 3. Firstly, the writing operation is explained. When a current is caused to flow in a prescribed direction of the bit line BL and a current is caused to flow the digit line DL, a first resultant magnetic field by the current of both is applied to the magneto resistance element TMR. Then, the magnetization direction of the recording layer RL of the magneto resistance element comes to be aligned with the direction of the first resultant magnetic field (first direction).

On the other hand, when a current flows in the direction opposite to the above-described prescribed direction of the bit line BL, and a current flows through the digit line DL, a second resultant magnetic field is generated in a direction differing from that of the first resultant magnetic field. Then, the magnetization direction of the recording layer RL comes to be aligned with the direction of the second resultant magnetic field. This causes the magnetization direction of the recording layer RL to coincide with the second direction that is opposite to the first direction.

As described above, by causing a current to flow through the digit line DL and controlling the direction of the current flowing through the bit line BL, it is possible to control the magnetization direction of the recording layer RL to have the first direction or the second direction. This means that the binary state of “0” and “1” may be stored by associating them with the magnetization directions of the recording layer RL. After that, even in a state where the current is made off, the magnetization direction of the recording layer RL is held. Meanwhile, the magnetization direction of the fixed layer FL does not change even when the first resultant magnetic field or the second resultant magnetic field is generated.

Next, the reading operation is explained. In the case of the reading operation, the digit line DL is not involved, and a current is caused to flow as follows. That is, in a state where the access transistor ATR is turned on, a current is supplied through such a channel as the bit line BL→the magneto resistance element TMR→the bottom electrode BE→the plug PLG4→the wiring L3→the plug PLG3→the wiring L2→the plug PLG2→the wiring L1→the plug PLG1→the drain region (deep n-type impurity diffusion region NR (left))→the channel region→the source region (deep n-type impurity diffusion region NR (right))→the source line (not shown). In this manner, the change of the resistance value against the current flowing through the magneto resistance element TMR is detected with a sense amplifier (not shown). At this time, when the magnetization direction of the recording layer RL is in parallel with that of the fixed layer FL, the resistance value of the magneto resistance element TMR becomes low. On the other hand, when the magnetization direction of the recording layer RL is antiparallel with that of the fixed layer FL, the resistance value of the magneto resistance element TMR becomes high. Accordingly, the binary state of the recording layer RL is reflected on the magnitude of the resistance value of the magneto resistance element TMR, and is read out to the outside. As described above, the information (data) stored in the magneto resistance element TMR may be read out. By arranging such memory cells in a matrix shape, an MRAM with a large capacity may be realized.

The MRAM in the Embodiment 1 has the above-described constitution, and, hereinafter, the characteristic points thereof are explained while referring to FIG. 3. In FIG. 3, a first characteristic of the MRAM in the Embodiment 1 lies in the point that the interval between the magneto resistance element TMR and the digit line DL is shortened. This enables the magnitude of the magnetic field occurring for the magneto resistance element TMR to be maintained even when the rewriting current caused to flow through the digit line DL is reduced. That is, the magnetic field generated by the rewriting current flowing through the digit line DL occurs in the shape of concentric circles in such a direction that a right-hand screw advances, relative to the flow direction of the rewriting current. And, a larger interval from the digit line DL gives a magnetic field having a smaller magnitude. In other words, a location nearer to the digit line DL has a greater magnetic field. Accordingly, when the digit line DL and the magneto resistance element TMR are constituted so as to have a small interval, as is the case for the Embodiment 1, the information stored in the magneto resistance element TMR may sufficiently be rewritten even when the magnitude of the rewriting current caused to flow through the digit line DL is made small. This means that the rewriting current for rewriting the information stored in the magneto resistance element TMR may be reduced, and that the lowering of the power consumption of the MRAM may be promoted.

Specifically, in ordinary MRAMs, the interval between the bottom surface of the bottom electrode BE and the upper surface of the digit line DL is around 200 nm. However, in the Embodiment 1, the interval between the bottom surface of the bottom electrode BE and the upper surface of the digit line DL is set to be around 100 nm. Consequently, the interval between the digit line DL and the magneto resistance element TMR is about one half. Therefore, when a magnetic field having the same magnitude is to be generated for the magneto resistance element TMR, in the MRAM in the Embodiment 1, the rewriting current caused to flow through the digit line DL may be reduced to about one-half according to the relation between the magnetic field H to be generated and the current I caused to flow (H=I/(2πr)).

Further, a second characteristic of the Embodiment 1 lies in the point that the cladding structure containing a ferromagnetic film is given to the digit line DL. This enables the magnetic field generated by causing the rewriting current to flow through the digit line DL to be collected effectively to the magneto resistance element TMR. As the result, it is possible to reduce the magnitude of the rewriting current caused to flow through the digit line DL for generating the magnetic field for rewriting the information stored in the magneto resistance element TMR. That is, the MRAM in the Embodiment 1 gives such a remarkable effect as achieving the reduction of the rewriting current caused by the synergistic effect of the first characteristic point of shortening the interval between the magneto resistance element TMR and the digit line DL, and the second characteristic point of giving the cladding structure to the digit line DL.

In order to realize such a structure, it is necessary to devise the method of manufacturing the MRAM. This subject is explained. That is, the fact that the simple use of methods of manufacturing MRAMs having been used conventionally makes it difficult to manufacture the MRAM in the Embodiment 1 is explained while referring to the drawings.

Firstly, as shown in FIG. 6, the wiring L3 and the digit line DL are formed for the interlayer insulating film IL3 by using, for example, the Damascene method. On this occasion, the wiring L3 and the digit line DL are formed from a laminated film of the barrier conductor film BCF4 and the copper film CF3. Further, the barrier conductor film BCF4 constituting the wiring L3 and the digit line DL is formed from a film containing a ferromagnetic film. Accordingly, it is possible to say that the digit line DL has the cladding structure.

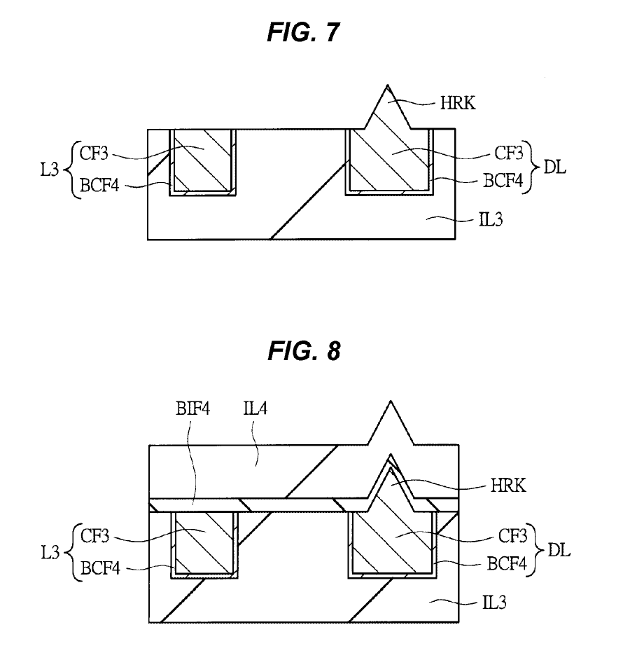

Next, a plasma treatment is performed for improving the adhesiveness between the digit line DL formed by embedding the copper film CF3 and the barrier insulating film to be formed subsequently over the digit line DL. The plasma treatment is usually performed by introducing a plasma by ammonia gas or a mixed gas of ammonia gas and nitrogen gas to the surface of the digit line DL. The plasma treatment at this time is performed with the inside temperature of the chamber set to be around 400° C. Accordingly, by the heat treatment at around 400° C. carried out in the plasma treatment, copper atoms constituting the digit line (copper wiring) tend to move easily in the wiring, and deposits in a projection shape (hereinafter, referred to as a hillock HRK) tend to occur easily near grain boundaries. Actually, in FIG. 7, the hillock HRK in a projection shape is formed for the surface (upper surface) of the digit line DL constituted from the copper wiring by the above-described plasma treatment.

Subsequently, as shown in FIG. 8, over the interlayer insulating film IL3 including over the digit line DL for which the hillock HRK is formed, the barrier insulating film BIF4 is formed, and, over the barrier insulating film BIF4, the interlayer insulating film IL4 is formed. On this occasion, the projection shape of the hillock HRK is reflected, consequently, on the barrier insulating film BIF4 and the interlayer insulating film IL4 formed over the digit line DL for which the hillock HRK is formed.

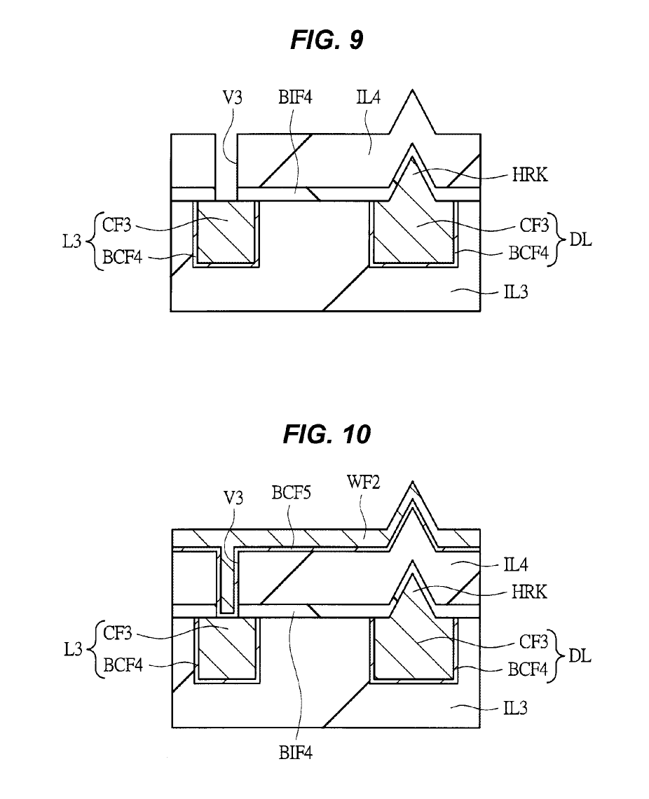

Then, as shown in FIG. 9, the via hole V3 that passes through the interlayer insulating film IL4 and the barrier insulating film BIF4 to reach the surface of the wiring L3 is formed by using a photolithographic technology and an etching technology. After that, as shown in FIG. 10, over the interlayer insulating film IL4 including the inside of the via hole V3, the barrier conductor film. BCF5 is formed, and, over the barrier conductor film BCF5, the tungsten film WF2 is formed.

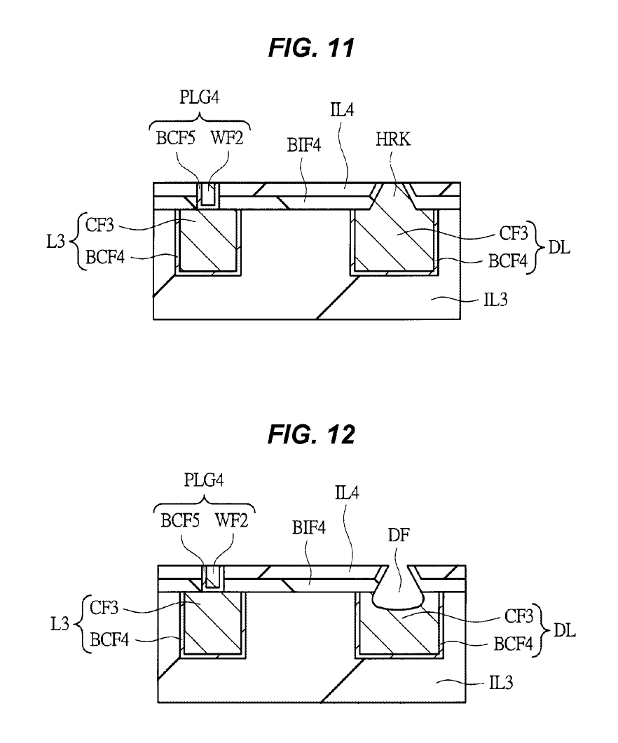

Next, as shown in FIG. 11, an unnecessary tungsten film WF2 and the barrier conductor film BCF5 formed over the interlayer insulating film IL4 are removed by using a Chemical Mechanical Polishing (CMP) method. Consequently, the plug PLG4 coupled to the wiring L3 is formed. At the same time, the hillock HRK formed on the surface of the digit line DL is exposed.

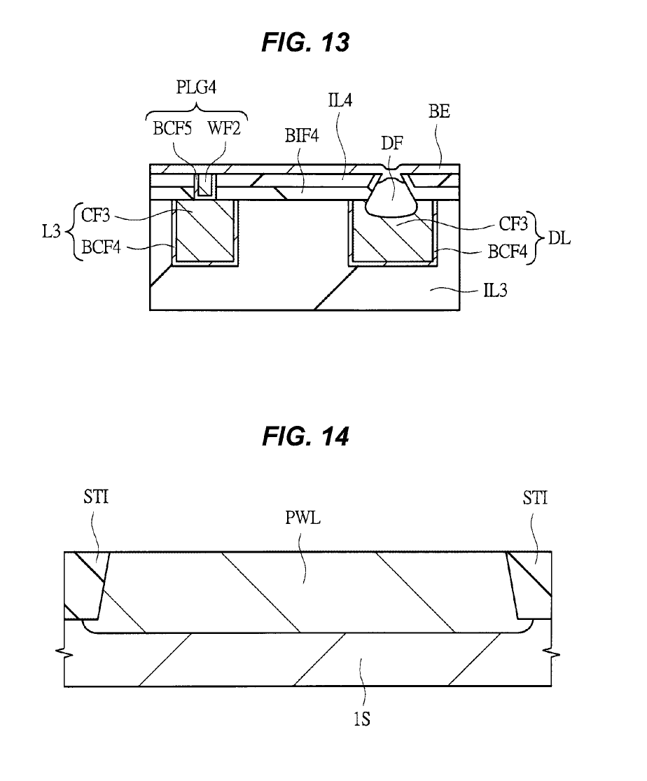

Then, as shown in FIG. 12, the copper film dissolves from the exposed hillock HRK to generate a cavity defect DF in the digit line DL. Then, as shown in FIG. 13, over the digit line DL for which the cavity defect DF occurs, the bottom electrode BE of the magneto resistance element is formed. On this occasion, the bottom electrode BE of the magneto resistance element is formed while reflecting the roughness of the surface of the digit line DL for which the cavity defect DF occurs, and, consequently, the roughness of the digit line DL is also reflected on the tunnel insulating film disposed over the bottom electrode BE via the fixed layer. As the result, the uniformity of the tunnel insulating film deteriorates to vary the resistance value of the magneto resistance element, and the rewriting property and the reading property of the MRAM deteriorate.

Consequently, when performing a plasma treatment by ammonia gas or a mixed gas of ammonia gas and nitrogen gas for the surface of the digit line DL, it is necessary to give a greater film thickness to the interlayer insulating film. IL4 to be formed over the barrier insulating film BIF4, in consideration of the occurrence of the hillock HRK over the digit line DL. That is, it is necessary to make the interlayer insulating film IL4 thicker so that the hillock HRK is not exposed even when the CMP treatment is performed for the interlayer insulating film IL4. This means that the interval between the digit line DL and the magneto resistance element formed over the interlayer insulating film IL4 becomes larger, and that, consequently, the reduction of the rewriting current flowing through the digit line DL may not be achieved.

Furthermore, when the digit line DL is constituted from the cladding structure, such a problem also occurs that the variation occurs in the rewriting current among memory cells by the plasma treatment by ammonia gas or a mixed gas of ammonia gas and nitrogen gas described above. For example, when the ferromagnetic film contained in the barrier conductor film. BCF4 is formed from NiFe alloy as an example of the cladding structure, a part of the NiFe alloy is nitrided by the plasma treatment by ammonia gas or a mixed gas of ammonia gas and nitrogen gas, and, for example, NiFe alloy and NiFeN alloy coexist in the ferromagnetic film. It is considered that, usually, the ratio of the formation of the NiFeN alloy differs in each of plural digit lines DL. Therefore, even when the same rewriting current is caused to flow through plural digit lines DL, since the ratio of the nitrided ferromagnetic film in the digit line DL varies, the magnetic field supplied to each of the memory cells also varies. This means that the rewriting current, which is caused to flow through each of the digit lines DL for giving a magnetic field necessary for rewriting the information stored in each of the memory cells, varies. That is, there occurs variation in the rewriting current among plural memory cells.

As described above, when the plasma treatment by ammonia gas or a mixed gas of ammonia gas and nitrogen gas, which is performed after the formation of the ordinary copper film CF3 for improving the adhesiveness between the copper film CF3 and the barrier insulating film BIF4, is directly applied to the digit line DL having the cladding structure, not only the reduction of the rewriting current of the MRAM, but also the suppression of the variation in the rewriting current among the memory cells becomes difficult.

That is, when the plasma treatment by ammonia gas or a mixed gas of ammonia gas and nitrogen gas is performed after the formation of the digit line DL having the cladding structure for improving the adhesiveness with the barrier insulating film, which is usually performed, the realization of such MRAM structure as that in the Embodiment 1 becomes difficult. Specifically, when the plasma treatment by ammonia gas or a mixed gas of ammonia gas and nitrogen gas is to be performed after the formation of the digit line DL, the interval between the digit line DL and the magneto resistance element must be set to be large for maintaining the property of the magneto resistance element. Furthermore, when the cladding structure is given to the digit line DL, the practice of the above-described plasma treatment results in the variation in the rewriting current among memory cells to deteriorate the property of the MRAM.

Accordingly, it is understood that the application of devices is required for manufacturing the MRAM in the Embodiment 1, which is provided with the first characteristic point of shortening the interval between the magneto resistance element TMR and the digit line DL and the second characteristic point of giving the cladding structure to the digit line DL. Hereinafter, the method of manufacturing the semiconductor device in the Embodiment 1 to which the device is applied is explained while referring to the drawings.

Firstly, as shown in FIG. 14, the semiconductor substrate 1S composed of a silicon single crystal into which such a p-type impurity as boron (B) is introduced is prepared. On this occasion, the semiconductor substrate 1S is in such a state as a semiconductor wafer of an approximate disk shape. Then, in the semiconductor substrate 1S, the element isolation region STI for separating elements from one another is formed. The element isolation region STI is formed so that elements do not interfere with each other. The element isolation region STI may be formed using, for example, a LOCOS (local oxidation of silicon) method or an STI (shallow trench isolation) method. For example, in the STI method, the element isolation region is formed as follows. That is, in the semiconductor substrate 1S, an element isolation trench is formed using the photolithographic technology and the etching technology. Then, so as to be embedded into the element isolation trench, a silicon oxide film is formed over the semiconductor substrate, and, after that, an unnecessary silicon oxide film formed over the semiconductor substrate is removed by a chemical mechanical polishing (CMP) method. This may form the element isolation region STI in which the silicon oxide film is embedded only into the element isolation trench.

Next, into the active region separated by the element isolation region STI, an impurity is introduced to form the p-type well PWL. The p-type well PWL is formed by introducing, for example, such a p-type impurity as boron into the semiconductor substrate 1S by an ion implantation method.

Subsequently, in the surface region of the p-type well PWL, a semiconductor region for forming a channel (not shown) is formed. The semiconductor region for forming a channel is formed for adjusting a threshold voltage forming the channel.

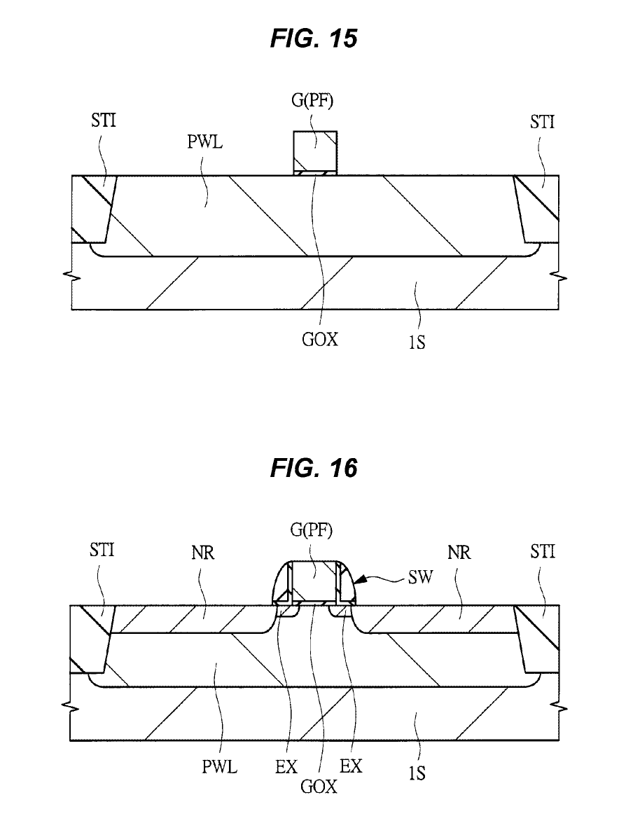

Next, as shown in FIG. 15, a gate insulating film GOX is formed over the semiconductor substrate 1S. The gate insulating film GOX is formed from, for example, a silicon oxide film, and may be formed by using, for example, a thermal oxidation method. However, the gate insulating film GOX is not limited to a silicon oxide film but may be changed variously, and, for example, the gate insulating film GOX may be formed from a silicon oxide nitride film (SiON). That is, a structure, in which nitrogen is segregated at the interface between the gate insulating film GOX and the semiconductor substrate 1S, may be adopted. The silicon oxide nitride film has a higher effect of suppressing the occurrence of an interface state in the film and reducing electron traps as compared with the silicon oxide film. Accordingly, it is possible to improve the hot carrier resistance of the gate insulating film GOX and to improve the dielectric strength. Moreover, the silicon oxide nitride film hardly allows an impurity to pass through, as compared with the silicon oxide film. Therefore, the use of the silicon oxide nitride film in the gate insulating film GOX may suppress the variation in the threshold voltage caused by the diffusion of impurities in the gate electrode to the semiconductor substrate 1S side. The silicon oxide nitride film may be formed by, for example, subjecting the semiconductor substrate 1S to a heat treatment in an atmosphere containing nitrogen such as NO, NO₂ or NH₃. The same effect may also be obtained by forming the gate insulating film GOX containing the silicon oxide film over the surface of the semiconductor substrate 1S, and, after that, subjecting the semiconductor substrate 1S to a heat treatment in an atmosphere containing nitrogen to segregate nitrogen at the interface between the gate insulating film GOX and the semiconductor substrate 1S.

The gate insulating film GOX may also be formed from a high permittivity film having a higher permittivity than, for example, the silicon oxide film. Conventionally, the silicon oxide film is used as the gate insulating film GOX from the standpoint of high dielectric strength and the excellent electric and physical stability of the silicon-silicon oxide interface. With the miniaturization of elements, however, an extremely thin thickness has been required for the gate insulating film GOX. The use of a thin silicon oxide film as the gate insulating film GOX results in the occurrence of a so-called tunneling current, which is a flow of electrons flowing through the channel of a MISFET to the gate electrode while tunneling the wall formed by the silicon oxide film.

Therefore, the use of a high permittivity film has begun, which makes it possible to increase a physical film thickness even when the capacity is the same by using a material having a higher permittivity than the silicon oxide film. The use of a high permittivity film may increase a physical film thickness while leaving the capacity as the same, to make the reduction of a leak current possible. In particular, the silicon nitride film also is a film having a higher permittivity than the silicon oxide film. However, in the Embodiment 1, the use of a high permittivity film having a higher permittivity than the silicon nitride film is desirable.

For example, as a high permittivity film having a higher permittivity than the silicon nitride film, a hafnium oxide film (HfO2 film) that is one of oxides of hafnium is used. However, in place of the hafnium oxide film, another hafnium-based insulating film may be used, such as an HfAlO film (hafnium aluminate film), an HfON film (hafnium oxynitride film), an HfSiO film (hafnium silicate film), or an HfSiON film (hafnium silicon oxynitride film). Furthermore, a hafnium-based insulating film formed by introducing an oxide such as tantalum oxide, niobium oxide, titanium oxide, zirconium oxide, lanthanum oxide, or yttrium oxide into these hafnium-based insulating films may also be used. Since hafnium-based insulating films have a higher permittivity than the silicon oxide film and the silicon oxide nitride film, as is the case for the hafnium oxide film, the use thereof gives the same effect as that obtained when the hafnium oxide film is used.

Subsequently, over the gate insulating film GOX, the polysilicon film PF is formed. The polysilicon film PF may be formed using, for example, a CVD method. Then, such an n-type impurity as phosphorous or arsenic is introduced into the polysilicon film PF formed in an access transistor formation region, using the photolithographic technology and the ion implantation method.

Next, the polysilicon film PF is processed by etching using a patterned resist film as a mask to form the gate electrode G.

Here, in the gate electrode G, an n-type impurity is introduced into the polysilicon film PF. Therefore, the value of the work function of the gate electrode G may be set to be a value near the conduction band of silicon (4.15 eV), and the threshold voltage of the access transistor may be reduced.

Subsequently, as shown in FIG. 16, the shallow n-type impurity diffusion region EX that matches with the gate electrode G is formed using the photolithographic technology and the ion implantation method. The shallow n-type impurity diffusion region EX is a semiconductor region.

Next, over the semiconductor substrate 1S, a laminated film of a silicon oxide film and a silicon nitride film is formed. The silicon oxide film and the silicon nitride film may be formed using, for example, a CVD method. Then, the silicon oxide film and the silicon nitride film are subjected to anisotropic etching to form the sidewall SW on the side wall of the gate electrode G. It is explained that the sidewall SW is formed from the laminated film of a silicon oxide film and a silicon nitride film. However, it is not limited to the above, but, for example, a sidewall SW of a single layer film of a silicon nitride film or a single layer film of a silicon oxide film may be formed.

Subsequently, the deep n-type impurity diffusion region NR that matches with the sidewall SW is formed using the photolithographic technology and the ion implantation method. The deep n-type impurity diffusion region NR is a semiconductor region. The deep n-type impurity diffusion region NR and the shallow n-type impurity diffusion region EX form the source region. In the same manner, the deep n-type impurity diffusion region NR and the shallow n-type impurity diffusion region EX form the drain region. The formation of the source region and the drain region by the shallow n-type impurity diffusion region EX and the deep n-type impurity diffusion region NR as described above makes it possible to give an LDD (Lightly Doped Drain) structure to the source region and the drain region.

After the deep n-type impurity diffusion region NR is formed as described above, a heat treatment at around 1000° C. is carried out, which activates the introduced impurity.

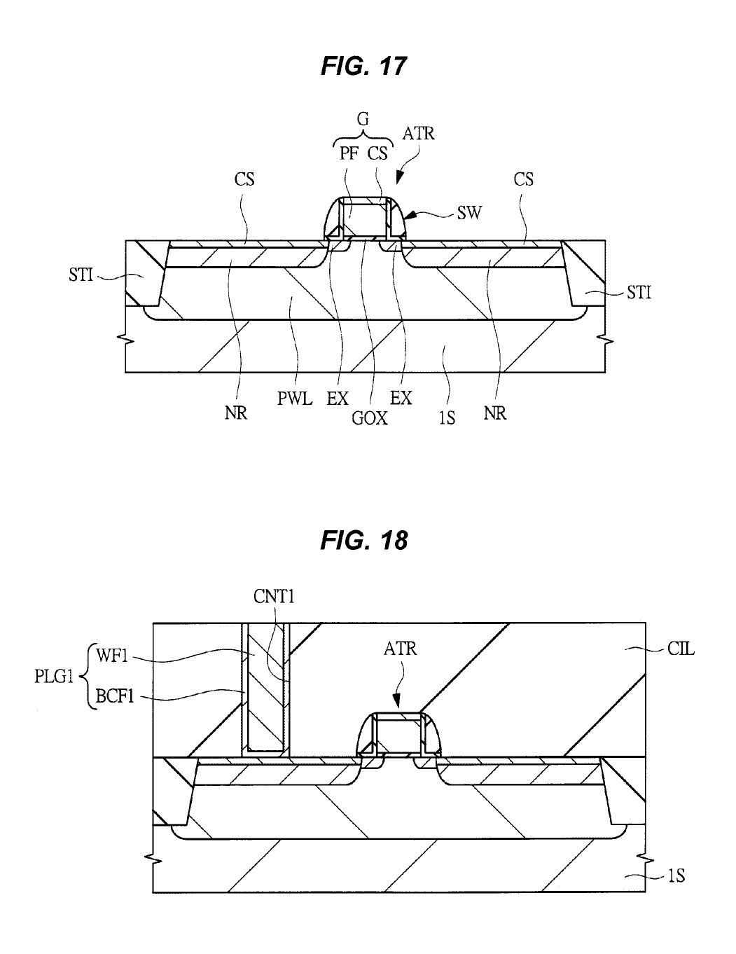

After that, as shown in FIG. 17, over the semiconductor substrate 1S, a cobalt film is formed. At this time, the cobalt film is formed so as to contact directly with the gate electrode G. Similarly, the cobalt film contacts directly with the deep n-type impurity diffusion region NR, too.

The cobalt film may be formed using, for example, a sputtering method. After the formation of the cobalt film, a heat treatment is carried out to cause the polysilicon film. PF and the cobalt film constituting the gate electrode G to react with each other, thus forming the cobalt silicide film CS. Consequently, a laminated structure of the polysilicon film PF and the cobalt silicide film CS is given to the gate electrode G. The cobalt silicide film CS is formed to make the resistivity of the gate electrode G lower. In the same manner, the above-described heat treatment causes silicon to react with the cobalt film also at the surface of the deep n-type impurity diffusion region NR, thus forming the cobalt silicide film CS. Consequently, also in the deep n-type impurity diffusion region NR, the reduction of the resistance may be achieved.

Then, an unreacted cobalt film is removed from over the semiconductor substrate 1S. Meanwhile, in the Embodiment 1, a constitution in which the cobalt silicide film CS is to be formed is adopted, but, for example, a constitution in which a nickel silicide film, a titanium silicide film, or a platinum silicide film is to be formed in place of the cobalt silicide film CS may also be adopted. As described above, the access transistor ATR may be formed over the semiconductor substrate 1S.

Subsequently, as shown in FIG. 18, over the semiconductor substrate 1S for which the access transistor ATR is formed, the contact interlayer insulating film CIL is formed. The contact interlayer insulating film CIL is formed so as to cover the access transistor ATR. Specifically, the contact interlayer insulating film CIL is formed from, for example, a laminated film of an ozone TEOS film formed by a thermal CVD method using ozone and TEOS as raw materials, and a plasma TEOS film formed by a plasma CVD method using TEOS as the raw material. Meanwhile, as a lower layer of the ozone TEOS film, for example, an etching stopper film containing a silicon nitride film may be formed.

The reason why the contact interlayer insulating film CIL is formed from the TEOS film is that the TEOS film is a film having good covering properties for steps of the foundation. The foundation over which the contact interlayer insulating film CIL is to be formed is in such a state that has roughness resulting from the formation of the access transistor ATR over the semiconductor substrate 1S. That is, since the access transistor ATR is formed over the semiconductor substrate 1S, the gate electrode G is formed on the surface of the semiconductor substrate 1S, resulting in the foundation having roughness. Accordingly, a film not having good covering properties for steps with roughness may not be embedded into the fine roughness to cause the occurrence of voids etc. Therefore, as the contact interlayer insulating film CIL, the TEOS film is used. Because, in the TEOS film using TEOS as the raw material, the TEOS being the raw material creates an intermediate before constituting a silicon oxide film, which moves easily on a film forming surface to improve the covering properties for the foundation with the steps.

Next, in the contact interlayer insulating film CIL, the contact hole CNT1 is formed using the photolithographic technology and the etching technology. The contact hole CNT1 is formed so as to pass through the contact interlayer insulating film. CIL to reach the drain region of the access transistor ATR formed over the semiconductor substrate 1S.

Subsequently, by embedding a metal film into the contact hole CNT1 formed in the contact interlayer insulating film CIL, the plug PLG1 is formed. Specifically, over the contact interlayer insulating film CIL in which the contact hole CNT1 is formed, a titanium/titanium nitride film (a titanium film and a titanium nitride film formed over the titanium film) to be the barrier conductor film BCF1 is formed using, for example, sputtering. The titanium/titanium nitride film is a film provided for preventing the diffusion of tungsten constituting a tungsten film into silicon, and a film for preventing damage that may be given to the contact interlayer insulating film CIL and the semiconductor substrate 1S by fluorine attack in a CVD method in which WF6 (tungsten fluoride) is subjected to a reduction treatment when the tungsten film is constituted.

Then, over the titanium/titanium nitride film, the tungsten film WF1 is formed. Consequently, on the inner wall (the side wall and the bottom surface) of the contact hole CNT1, the barrier conductor film BCF1 is formed, and the tungsten film WF1 is formed so as to be embedded into the contact hole CNT1 over the barrier conductor film BCF1. After that, an unnecessary barrier conductor film BCF1 and tungsten film WF1 formed over the contact interlayer insulating film CIL are removed by the CMP (Chemical Mechanical Polishing) method. Consequently, the plug PLG1, in which the barrier conductor film BCF1 and the tungsten film WF1 are embedded only into the contact hole CNT1, may be formed.

Subsequently, the surface of the contact interlayer insulating film CIL in which the plug PLG1 is formed is subjected to a plasma treatment. Specifically, the semiconductor substrate 1S is carried in a chamber, and ammonia gas or a mixed gas containing ammonia gas and nitrogen gas is introduced into the chamber. After that, the inside temperature of the chamber is raised to about 400° C. to turn the ammonia gas or the mixed gas introduced into the chamber into a plasma. Thus, the surface of the contact interlayer insulating film CIL is subjected to the plasma treatment by the plasma derived from the ammonia gas or the nitrogen gas.

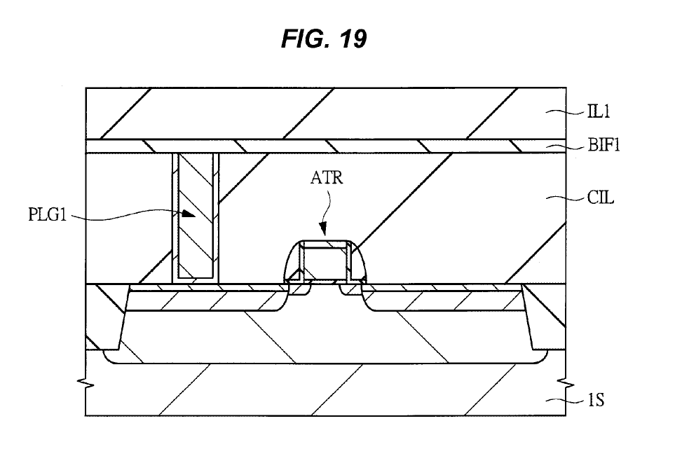

After that, as shown in FIG. 19, over the contact interlayer insulating film CIL in which the plug PLG1 is formed, the barrier insulating film BIF1 is formed by using, for example, a CVD method, and, over the barrier insulating film BIF1, the interlayer insulating film IL1 is formed. The barrier insulating film BIF1 is formed from a film containing, for example, any of a SiN film (silicon nitride film), a SiON film (silicon oxide nitride film), a SiC film (silicon carbide film), a SiCN film (silicon carbide nitride film), and a SiCO film. The interlayer insulating film IL1 is formed from a silicon oxide film or a low-permittivity film having a lower permittivity than the silicon oxide film. Specifically, the interlayer insulating film IL1 contains, for example, a SiOC film, a HSQ (hydrogen silsesquioxane, a silicon oxide film having a Si—H bond or hydrogen-containing silsesquioxane formed by a coating process) film, aMSQ (methyl silsesquioxane, a silicon oxide film having a Si—C bond or carbon-containing silsesquioxane formed by a coating process) film, a TEOS film, a silicon oxide film, or a SiOF film. On this occasion, since the surface of the contact interlayer insulating film CIL has been subjected to the plasma treatment by ammonia gas, the adhesiveness between the contact interlayer insulating film CIL and the barrier insulating film BIF1 is improved.

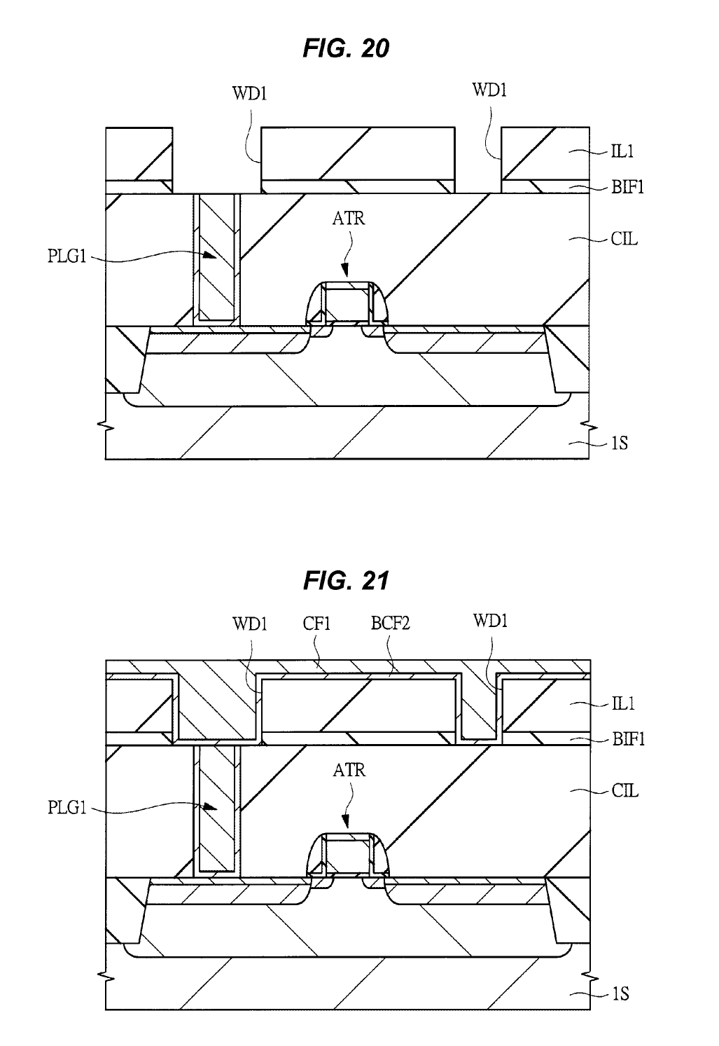

Then, as shown in FIG. 20, the wiring trench WD1 passing through the interlayer insulating film IL1 and the barrier insulating film BIF1 is formed by using the photolithographic technology and the etching technology. The wiring trench WD1 is formed so that it passes through the interlayer insulating film IL1 and the barrier insulating film BIF1 and the bottom surface thereof reaches the contact interlayer insulating film CIL. Consequently, at the bottom portion of the wiring trench WD1, the surface of the plug PLG1 is exposed.

After that, as shown in FIG. 21, over the interlayer insulating film IL1 for which the wiring trench WD1 is formed, the barrier conductor film BCF2 is formed. Specifically, the barrier conductor film BCF2 contains tantalum (Ta), titanium (Ti), ruthenium (Ru), tungsten (W), manganese (Mn), nitride or nitriding silicide thereof, or a laminated film thereof, and may be formed by using, for example, a sputtering method. In other words, the barrier conductor film BCF2 may be formed from either a metal material film containing any of metal materials of tantalum, titanium, ruthenium and manganese, or a film of the compound of the metal material and any of elements of Si, N, O and C.

Subsequently, over the barrier conductor film BCF2 formed inside the wiring trench WD1 and over the interlayer insulating film IL1, a seed film containing, for example, a thin copper film is formed by a sputtering method. Then, by an electrolytic plating method using the seed film as an electrode, the copper film CF1 is formed. The copper film CF1 is formed so as to be embedded into the wiring trench WD1. The copper film CF1 is formed from, for example, a film containing copper as the main constituent. Specifically, it is formed from copper (Cu) or a copper alloy (an alloy of copper (Cu) with aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), indium (In), lanthanoid-based metal or actinoid-based metal).

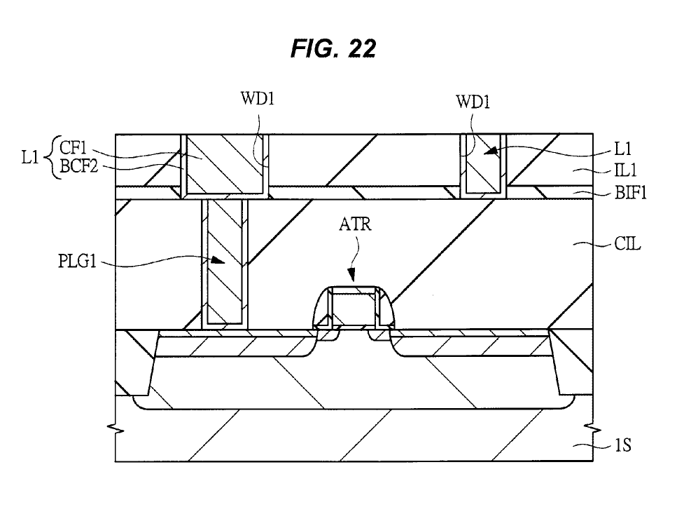

Next, as shown in FIG. 22, an unnecessary barrier conductor film BCF2 and copper film CF1 formed over the interlayer insulating film IL1 are removed by the CMP method. Consequently, the wiring L1, wherein the barrier conductor film BCF2 and the copper film CF1 are embedded into the wiring trench WD1, may be formed.

Subsequently, the surface of the interlayer insulating film IL1 for which the wiring L1 is formed is subjected to a plasma treatment. Specifically, the semiconductor substrate 1S is carried in a chamber, and ammonia gas or a mixed gas containing ammonia gas and nitrogen gas is introduced into the chamber. After that, the inside temperature of the chamber is raised to about 400° C. to turn the ammonia gas or the mixed gas introduced into the chamber into a plasma. Thus, the surface of the interlayer insulating film IL1 is subjected to the plasma treatment by the plasma derived from the ammonia gas or the nitrogen gas.

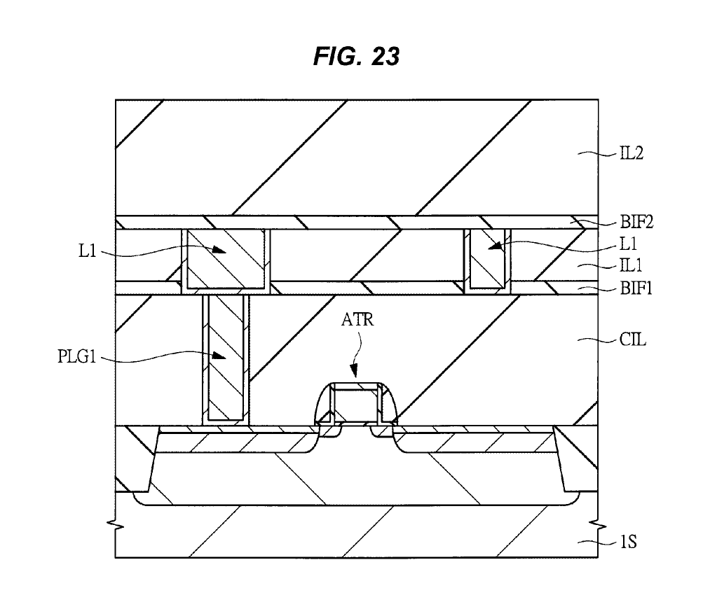

After that, as shown in FIG. 23, over the interlayer insulating film IL1 for which the wiring L1 is formed, the barrier insulating film BIF2 is formed by using, for example, a CVD method, and, over the barrier insulating film BIF2, the interlayer insulating film IL2 is formed. The barrier insulating film BIF2 is formed from, for example, a film containing any of a SiN film (silicon nitride film), a SiON film (silicon oxide nitride film), a SiC film (silicon carbide film), a SiCN film (silicon carbide nitride film), and a SiCO film. Furthermore, the interlayer insulating film IL2 is formed from a silicon oxide film or a low-permittivity film having a lower permittivity than a silicon oxide film. Specifically, the interlayer insulating film IL1 contains, for example, a SiOC film, a HSQ (hydrogen silsesquioxane, a silicon oxide film that is formed by a coating process and has a Si—H bond, or a hydrogen-containing silsesquioxane) film or a MSQ (methyl silsesquioxane, a silicon oxide film that is formed by a coating process and has a Si—C bond, or a carbon-containing silsesquioxane) film, a TEOS film, a silicon oxide film, or a SiOF film. On this occasion, since the surface of the interlayer insulating film IL1 has been subjected to the plasma treatment by ammonia gas, the adhesiveness between the wiring L1 and interlayer insulating film IL1, and the barrier insulating film BIF2 is improved.

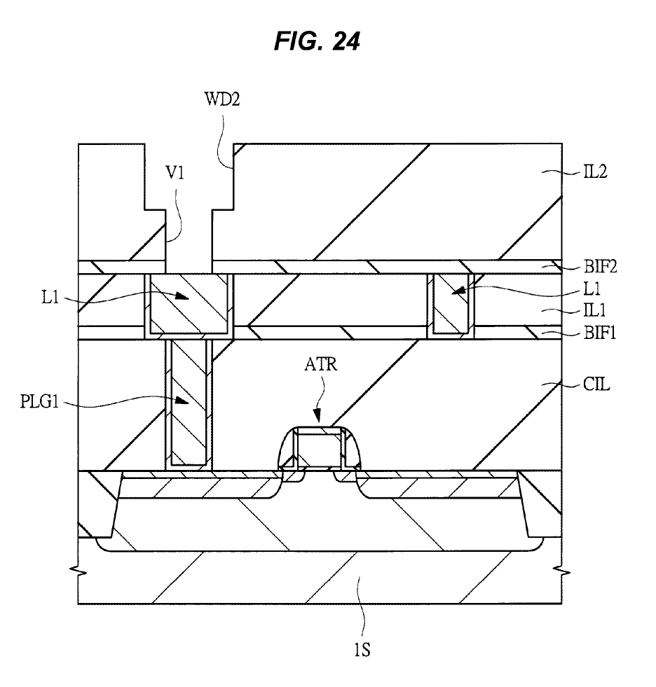

Then, as shown in FIG. 24, the wiring trench WD2 and the via hole V1 passing through the interlayer insulating film IL2 and the barrier insulating film BIF2 are formed by using the photolithographic technology and the etching technology. The wiring trench WD2 and the via hole V1 pass through the interlayer insulating film IL2 and the barrier insulating film BIF2. That is, consequently, the surface of the wiring L1 is exposed at the bottom of the via hole V1.

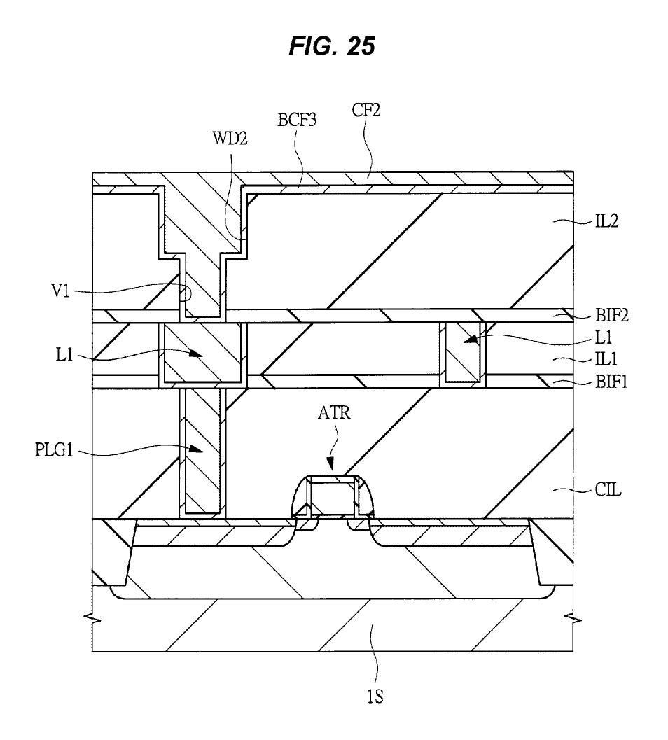

After that, as shown in FIG. 25, over the interlayer insulating film IL2 in which the wiring trench WD2 and the via hole V1 are formed, the barrier conductor film BCF3 is formed. Specifically, the barrier conductor film BCF3 contains tantalum (Ta), titanium (Ti), ruthenium (Ru), tungsten (W), manganese (Mn), or nitride or nitriding silicide thereof, or a laminated film thereof, and may be formed by using, for example, a sputtering method. In other words, the barrier conductor film BCF3 may be formed from either a metal material film containing any of metal materials of tantalum, titanium, ruthenium and manganese, or a film of the compound of the metal material and any of elements of Si, N, O and C.

Subsequently, over the barrier conductor film BCF3 formed inside the wiring trench WD2 and via hole V1 and over the interlayer insulating film IL2, a seed film containing, for example, a thin copper film is formed by a sputtering method. Then, by an electrolytic plating method using the seed film as an electrode, the copper film CF2 is formed. The copper film CF2 is formed so as to be embedded into the wiring trench WD2 and the via hole V1. The copper film CF2 is formed from, for example, a film containing copper as the main constituent. Specifically, it is formed from copper (Cu) or a copper alloy (an alloy of copper (Cu) with aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), indium (In), lanthanoid-based metal or actinoid-based metal).

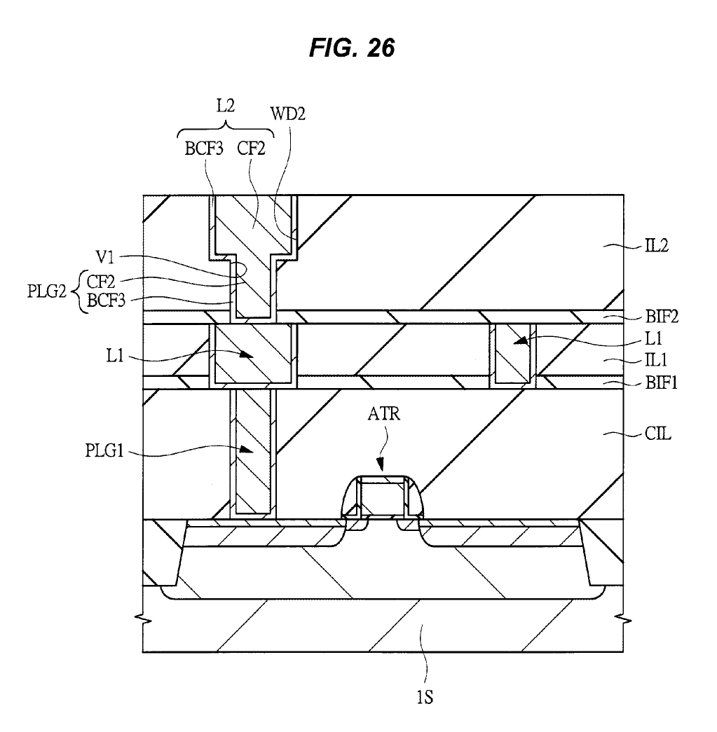

Next, as shown in FIG. 26, an unnecessary barrier conductor film BCF3 and copper film CF2 formed over the interlayer insulating film IL2 are removed by the CMP method. Consequently, the wiring L2, wherein the barrier conductor film BCF3 and the copper film CF2 are embedded into the wiring trench WD2, and the plug PLG2, wherein the barrier conductor film BCF3 and the copper film CF2 are embedded into the via hole V1, may be formed.

Subsequently, the surface of the interlayer insulating film IL2 for which the wiring L2 is formed is subjected to a plasma treatment. Specifically, the semiconductor substrate 1S is carried in a chamber, and ammonia gas or a mixed gas containing ammonia gas and nitrogen gas is introduced into the chamber. After that, the inside temperature of the chamber is raised to about 400° C. to turn the ammonia gas or the mixed gas introduced into the chamber into a plasma. Thus, the surface of the interlayer insulating film IL2 is subjected to the plasma treatment by the plasma derived from the ammonia gas or the nitrogen gas.

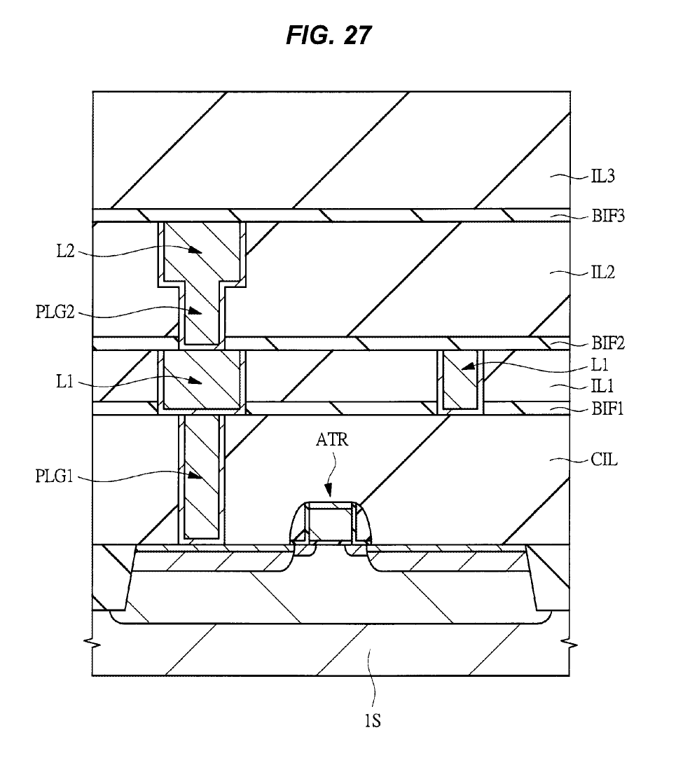

After that, as shown in FIG. 27, over the interlayer insulating film IL2 for which the wiring L2 is formed, the barrier insulating film BIF3 is formed by using, for example, a CVD method, and, over the barrier insulating film BIF3, the interlayer insulating film IL3 is formed. The barrier insulating film BIF3 is formed from, for example, a film containing any of a SiN film (silicon nitride film), a SiON film (silicon oxide nitride film), a SiC film (silicon carbide film), a SiCN film (silicon carbide nitride film), and a SiCO film. Furthermore, the interlayer insulating film IL3 is formed from a silicon oxide film or a low-permittivity film having a lower permittivity than a silicon oxide film. Specifically, the interlayer insulating film IL1 contains, for example, a SiOC film, a HSQ (hydrogen silsesquioxane, a silicon oxide film that is formed by a coating process and has a Si—H bond, or a hydrogen-containing silsesquioxane) film or a MSQ (methyl silsesquioxane, a silicon oxide film that is formed by a coating process and has a Si—C bond, or a carbon-containing silsesquioxane) film, a TEOS film, a silicon oxide film, or a SiOF film. On this occasion, since the surface of the interlayer insulating film IL2 has been subjected to the plasma treatment by ammonia gas, the adhesiveness between the wiring L2 and the interlayer insulating film IL2, and the barrier insulating film BIF3 is improved.

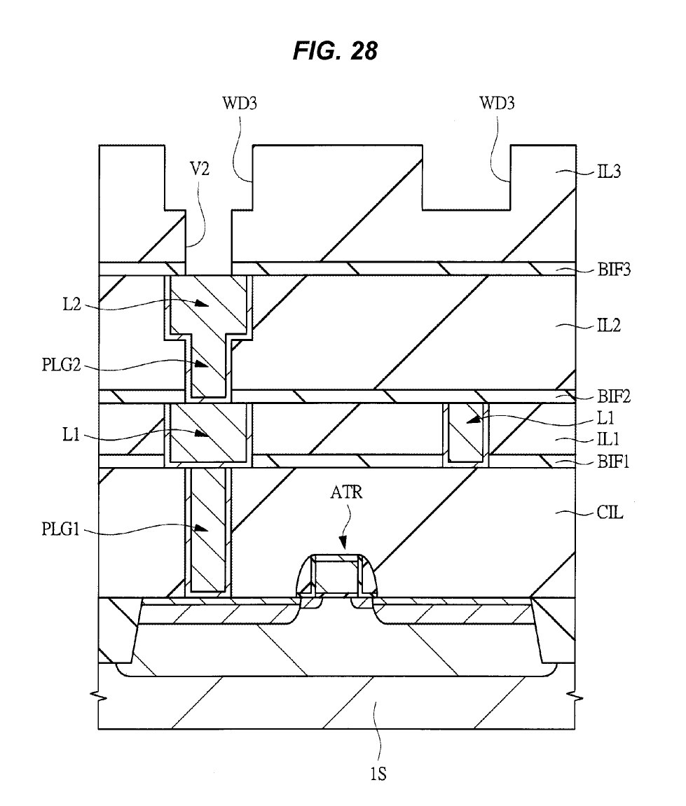

Then, as shown in FIG. 28, the wiring trench WD3 and the via hole V2 passing through the interlayer insulating film IL3 and the barrier insulating film BIF3 are formed by using the photolithographic technology and the etching technology. The wiring trench WD3 and the via hole V2 pass through the interlayer insulating film IL3 and barrier insulating film BIF3. That is, consequently, at the bottom surface of the via hole V2, the surface of the wiring L2 is exposed. Meanwhile, in the same layer as the wiring trench WD3 connected with the via hole V2, the wiring trench WD3 for the digit line is also formed.

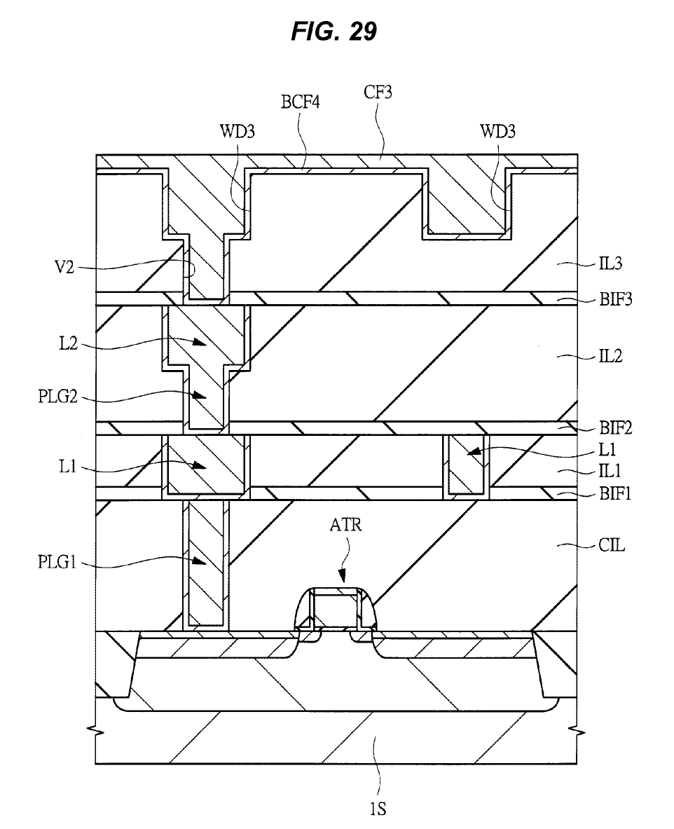

After that, as shown in FIG. 29, over the interlayer insulating film IL3 in which the wiring trench WD3 and the via hole V2 are formed, the barrier conductor film BCF4 is formed. Specifically, the constitution of the barrier conductor film BCF4 differs from that of the barrier conductor film BCF2 and the barrier conductor film BCF3 constituting apart of the wiring L2 and a part of the wiring L1. That is, the barrier conductor film BCF4 is constituted so as to contain a ferromagnetic film having a high permeability. For example, the barrier conductor film BCF4 contains a laminated film containing a tantalum nitride film, a first tantalum film formed over the tantalum nitride film, a ferromagnetic film formed over the first tantalum film, and a second tantalum film formed over the ferromagnetic film. However, films constituting the barrier conductor film BCF4 other than the ferromagnetic film may be formed from a tantalum film, a titanium film, a ruthenium film, a tungsten film, a manganese film, or a film containing any of nitride films and nitriding silicide films thereof.

The ferromagnetic film contained in the barrier conductor film BCF4 is formed so as to contain any of, for example, a nickel film, an iron film, a cobalt film, and an alloy film containing an alloy of these films, or a film formed by adding any element of chromium, molybdenum, aluminum, silicon, zirconium and boron to the nickel film, the iron film, the cobalt film or the alloy film.

Subsequently, over the barrier conductor film BCF4 formed inside the wiring trench WD3 and the via hole V2 and over the interlayer insulating film IL3, a seed film containing, for example, a thin copper film is formed by a sputtering method. Then, by an electrolytic plating method using the seed film as an electrode, the copper film CF3 is formed. The copper film CF3 is formed so as to be embedded into the wiring trench WD3 and the via hole V2. The copper film CF3 is formed from, for example, a film containing copper as the main constituent. Specifically, it is formed from copper (Cu) or a copper alloy (an alloy of copper (Cu) with aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), indium (In), lanthanoid-based metal or actinoid-based metal).

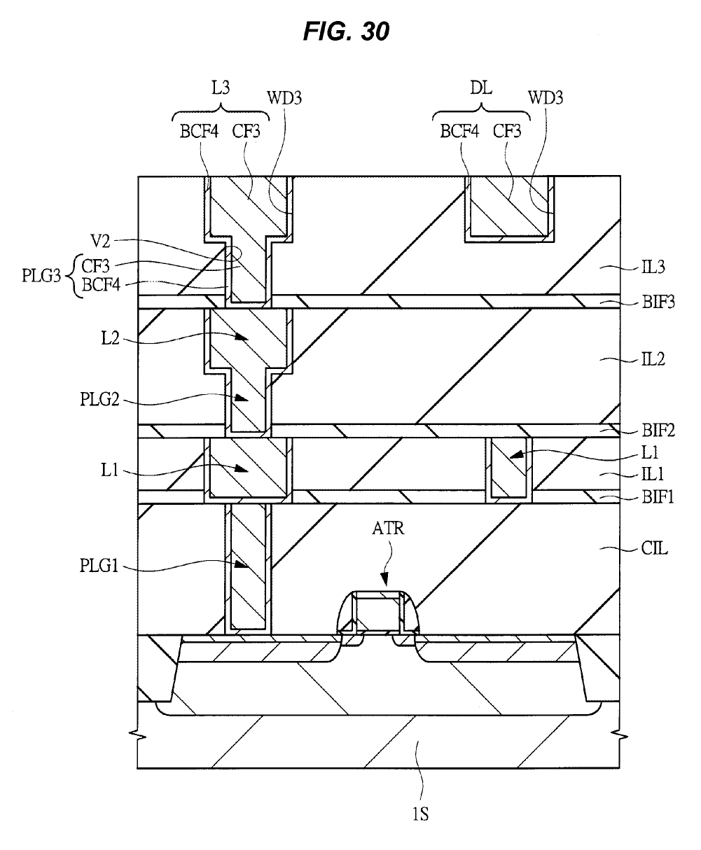

Next, as shown in FIG. 30, an unnecessary barrier conductor film BCF4 and copper film CF3 formed over the interlayer insulating film IL3 are removed by the CMP method. Consequently, the wiring L3 in which the barrier conductor film BCF4 and the copper film CF3 are embedded into the wiring trench WD3, and the plug PLG3 in which the barrier conductor film BCF4 and the copper film CF3 are embedded into the via hole V2 may be formed. Furthermore, in the same layer as the wiring L3, the digit line DL in which the barrier conductor film BCF4 and the copper film CF3 are embedded into the wiring trench WD3 may be formed. In the Embodiment 1, since a constitution, in which the barrier conductor film BCF4 contains the ferromagnetic film, is adopted, the digit line DL has a cladding structure.

Subsequently, the surface of the interlayer insulating film IL3 for which the wiring L3 and the digit line DL are formed is subjected to a plasma treatment. The plasma treatment characterizes the Embodiment 1. Hereinafter, the plasma treatment being the characteristic of the Embodiment 1 is explained.

Firstly, the semiconductor substrate 1S is carried in a chamber, and a mixed gas including molecules containing nitrogen and inert molecules not containing nitrogen is introduced into the chamber. On this occasion, the mixed gas is introduced under such a condition that the flow rate of the inert molecules not containing nitrogen is larger than that of the molecules containing nitrogen, and the mixed gas is turned into plasma to perform the plasma treatment.

Specifically, as the molecules containing nitrogen, ammonia gas is used, and as the inert molecules not containing nitrogen, hydrogen gas, helium or argon is used. Then, the mixed gas is introduced into the chamber so that the flow rate of the molecules containing nitrogen (ammonia gas) is 2% or less relative to the flow rate of the inert molecules not containing nitrogen (hydrogen gas, helium, argon). The plasma treatment is performed on this occasion under such conditions as the inside pressure of the chamber of 560 Pa, the treatment time of 20 seconds and the power of 150 W. Furthermore, the plasma treatment is performed at the inside temperature of the chamber of about 280° C.

Advantages of the plasma treatment are explained. A first advantage lies in that the temperature of the plasma treatment is 280° C., that is, the temperature is lower than the temperature of conventional plasma treatments (about 400° C.) that use ammonia gas singly. This may suppress the occurrence of the hillock by thermal loading by the plasma treatment for the surface of the digit line DL containing a copper wiring. That is, in the plasma treatment in the Embodiment 1, the treatment temperature may be lowered to around 280° C. Therefore, the occurrence of the hillock for the surface of the digit line DL may be suppressed. Because, the hillock has such nature that it occurs more easily when the treatment temperature by the plasma treatment becomes higher. Thus, in the Embodiment 1, the occurrence of the hillock for the digit line DL may be suppressed, and, therefore, when the interlayer insulating film is formed over the digit line DL and the interlayer insulating film is subjected to the CMP treatment, the exposure of the hillock may be suppressed. This means that the occurrence of the cavity defect caused by the exposure of the hillock may be suppressed.

When the cavity defect occurs, consequently, the bottom electrode of the magneto resistance element is formed over the digit line DL for which the cavity defect is formed. On this occasion, the bottom electrode of the magneto resistance element is formed while reflecting the roughness of the surface of the digit line with the cavity defect. As the result, also to the tunnel insulating film to be disposed over the bottom electrode via the fixed layer, the roughness of the digit line DL is reflected. Therefore, the uniformity of the tunnel insulating film deteriorates and the resistance value of the magneto resistance element varies, and the rewriting property and the reading property of the MRAM deteriorate.

In contrast, in the Embodiment 1, since the occurrence of the cavity defect may be suppressed as described above, the flatness over the digit line DL may be secured. Consequently, the uniformity of the tunnel insulating film constituting the magneto resistance element may be maintained, and the deterioration of the rewriting properties and reading properties of the MRAM may be prevented. Accordingly, in the Embodiment 1, since the flatness over the digit line DL may be secured and the property deterioration of the MRAM may be suppressed, the interval between the digit line DL and the magneto resistance element may be made smaller. This means that the rewriting current flowing through the digit line DL may be reduced. Accordingly, by carrying out the plasma treatment in the Embodiment 1, the structure, in which the interval between the upper surface of the digit line DL and the bottom surface of the bottom electrode of the magneto resistance element is 100 nm or less, may be realized.

Furthermore, as to the first advantage, the plasma treatment in the Embodiment 1 has such an advantage that the treatment time of the plasma treatment is as short as 20 seconds. In addition, there is such an advantage that the actual temperature of the semiconductor substrate 1S is lower than the treatment temperature of 280° C., because hydrogen gas or helium having a high thermal conductivity is used. Accordingly, in addition to the first advantage that the treatment is carried out in a chamber having an inside temperature of 280° C., in the Embodiment 1, such a remarkable effect may be obtained as suppressing sufficiently the occurrence of the hillock to improve the flatness of the digit line DL, as the result of the synergistic effect of a shorter treatment time than that of the conventional plasma treatment that uses ammonia gas singly, and the use of hydrogen gas or helium gas having a high thermal conductivity.

Next, a second advantage lies in that nitrogen gas is not used and ammonia gas is greatly diluted with an inert gas in the plasma treatment. This may suppress the nitridation of the ferromagnetic film contained in the digit line DL of the cladding structure.

For example, when the ferromagnetic film is to be formed from NiFe alloy, in conventional plasma treatments that use ammonia gas singly or a mixed gas of ammonia gas and nitrogen gas, the ammonia gas in a high concentration nitrides a part of the NiFe alloy and, consequently, NiFe alloy and NiFeN alloy coexist in the ferromagnetic film. On this occasion, the ratio of the NiFeN alloy formation is considered, usually, to be different for each of plural digit lines DL. Therefore, since the nitridation ratio of the ferromagnetic film in the digit line DL varies, the magnetic field supplied to respective memory cells also varies even when the same rewriting current is caused to flow through the plural digit lines DL. This means that the rewriting current, which is caused to flow through respective digit lines DL for supplying the magnetic field necessary for rewriting the information stored in respective memory cells, differs from one another. That is, the variation occurs in the rewriting current among plural memory cells.

In contrast, in the plasma treatment in the Embodiment 1, the nitridation of the ferromagnetic film constituting the digit line DL may be suppressed, because nitrogen gas is not used and ammonia gas is greatly diluted with an inert gas. Consequently, almost no ferromagnetic film is nitrided, and the composition of respective ferromagnetic films contained in plural digit line DL becomes uniform. Accordingly, when the same rewriting current is caused to flow through plural digit lines DL, approximately uniform magnetic fields are supplied to respective memory cells. As the result, the variation in the rewriting current among memory cells may be reduced.

Here, ammonia gas, which is an atom containing nitrogen, is a gas used in order to improve the adhesiveness between the digit line DL containing a copper wiring and the barrier insulating film. However, when a plasma treatment with the ammonia gas alone is performed, the treatment temperature becomes higher and the nitridation of the ferromagnetic film contained in the digit line DL occurs. Accordingly, in the Embodiment 1, ammonia gas, which is a molecule containing nitrogen, is used, and such an inert molecule as hydrogen gas, helium or argon is mixed. This makes it possible to lower the treatment temperature of the plasma treatment, and to dilute the concentration of the ammonia gas. That is, it may be said that the inert molecule (hydrogen gas, helium, argon) introduced in the Embodiment 1 has a function of enabling to lower the plasma treatment temperature and has a function of diluting the concentration of the ammonia gas. As the result, in the plasma treatment in the Embodiment 1 containing the inert molecule, the plasma treatment temperature may be lowered to suppress the occurrence of the hillock and to improve the flatness of the upper surface of the digit line DL. Moreover, the concentration of the ammonia gas may be diluted greatly to suppress the nitridation of the ferromagnetic film contained in the digit line DL. Accordingly, it is possible to realize easily the MRAM in which the interval between the digit line DL and the magneto resistance element is shortened and the cladding structure is given to the digit line DL. That is, according to the method of manufacturing a semiconductor device in the Embodiment 1, a semiconductor device, which realizes the reduction of the rewriting current and the reduction of the variation in the rewriting current at the same time, may be realized easily.

Meanwhile, in the plasma treatment in the Embodiment 1, the plasma treatment is performed with a mixed gas also containing ammonia gas, from the standpoint of improving the adhesiveness between the interlayer insulating film IL3 for which the digit line DL is formed and the barrier insulating film to be formed subsequently. However, from the standpoint of suppressing further the nitridation of the ferromagnetic film constituting the digit line DL to achieve the improvement of properties of the MRAM, the plasma treatment may also be performed with a gas not containing ammonia gas.

That is, the plasma treatment in the Embodiment 1 may also be performed using a gas composed of inert molecules not containing nitrogen. For example, as the gas composed of inert molecules not containing nitrogen, hydrogen gas may be used. The condition of the plasma treatment performed on this occasion may be set, for example, so that the flow rate of the hydrogen gas is 1000 sccm, the inside pressure of the chamber is 560 Pa, the treatment time is 20 seconds and the power is 150 W.

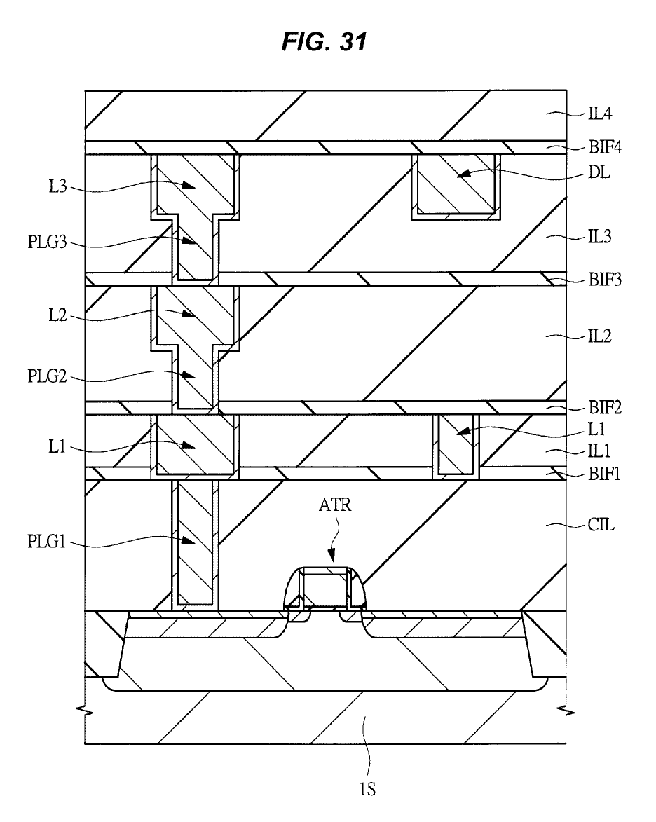

Subsequently, subsequent processes are explained. As shown in FIG. 31, over the interlayer insulating film IL3 for which the wiring L3 and the digit line DL are formed, the barrier insulating film BIF4 is formed by using, for example, a CVD method, and, over the barrier insulating film BIF4, the interlayer insulating film IL4 is formed. The barrier insulating film BIF4 is formed from a film containing, for example, any of a SiN film (silicon nitride film), a SiON film (silicon oxide nitride film), a SiC film (silicon carbide film), a SiCN film (silicon carbide nitride film), and a SiCO film. The interlayer insulating film IL4 is formed from a silicon oxide film etc. On this occasion, since the surface of the interlayer insulating film IL3 has been subjected to the plasma treatment according to the Embodiment 1, the adhesiveness between the wiring L3, digit line DL and interlayer insulating film IL3, and the barrier insulating film BIF4 is improved.

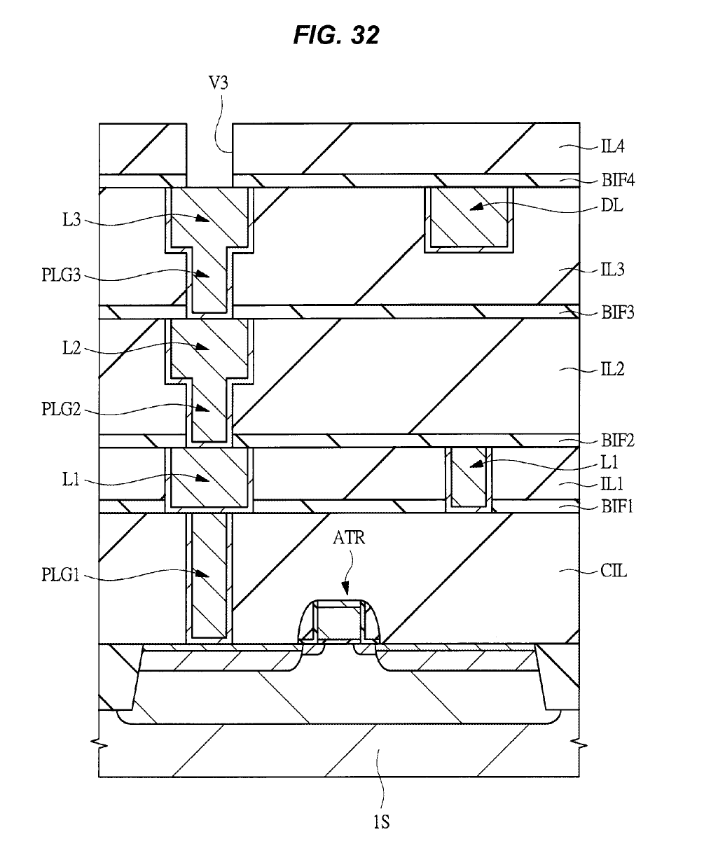

Then, as shown in FIG. 32, the via hole V3 passing through the interlayer insulating film IL4 and the barrier insulating film BIF4 is formed by using the photolithographic technology and the etching technology. Consequently, the surface of the wiring L3 is exposed at the bottom surface of the via hole V3.

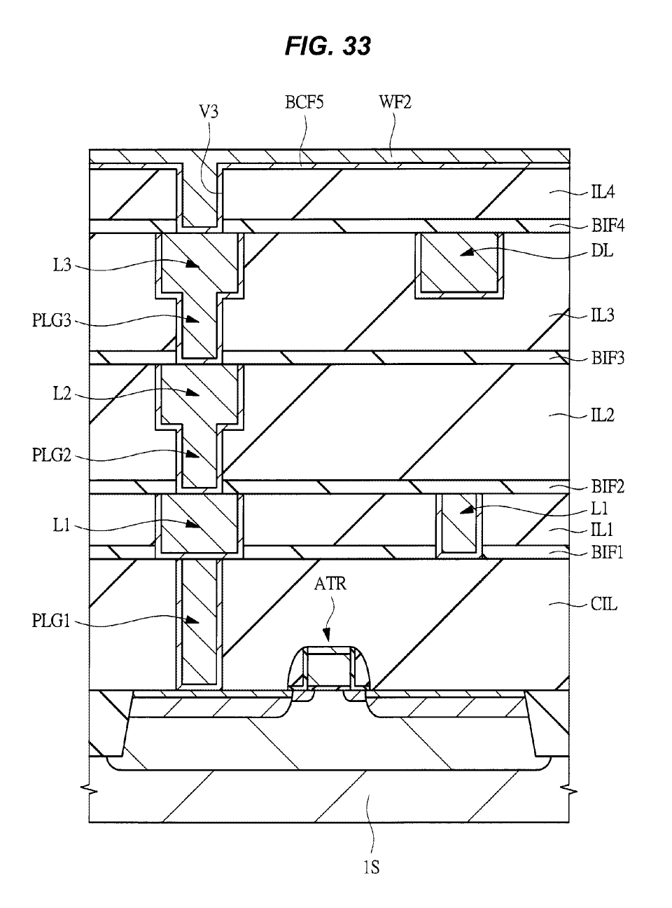

After that, as shown in FIG. 33, over the interlayer insulating film IL4 for which the via hole V3 is formed, the barrier conductor film BCF5 is formed. Specifically, the barrier conductor film BCF5 contains tantalum (Ta), titanium (Ti), ruthenium (Ru), tungsten (W), manganese (Mn) or nitride or nitriding silicide thereof, or a laminated film thereof, and may be formed by using, for example, a sputtering method. In other words, the barrier conductor film BCF5 may be formed from any film of metal material films containing any of metal materials of tantalum, titanium, ruthenium and manganese, and compound films of the metal materials and any of elements of Si, N, O and C.

Subsequently, over the barrier conductor film BCF5 formed inside the via hole V3 and over the interlayer insulating film IL4, for example, the tungsten film WF2 is formed by a CVD method. Meanwhile, in place of the tungsten film WF2, a copper film may be formed.

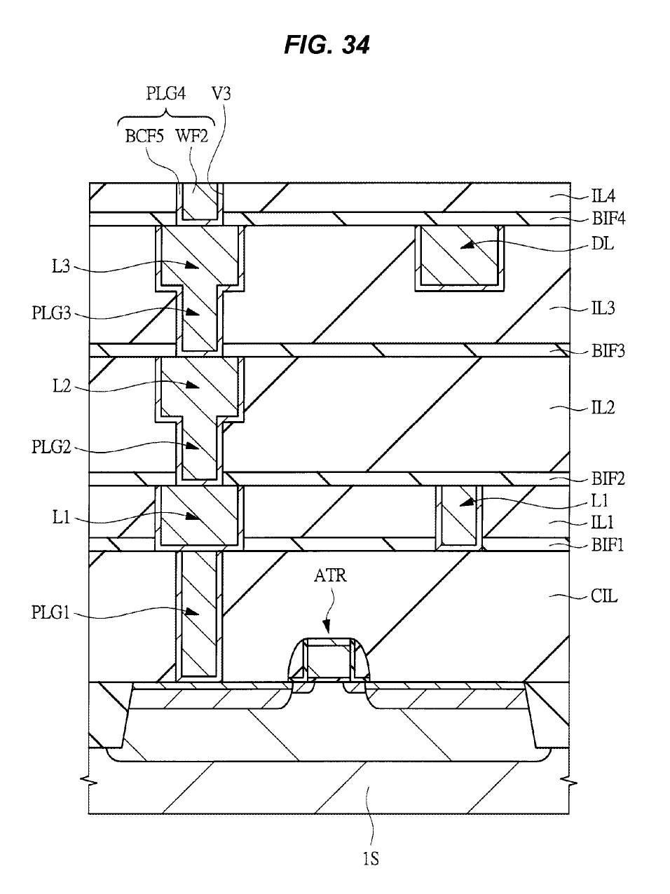

Next, as shown in FIG. 34, an unnecessary barrier conductor film BCF5 and tungsten film WF2 formed over the interlayer insulating film IL4 are removed by the CMP method. This may form the plug PLG4 in which the barrier conductor film BCF5 and the tungsten film WF2 are embedded into the via hole V3.

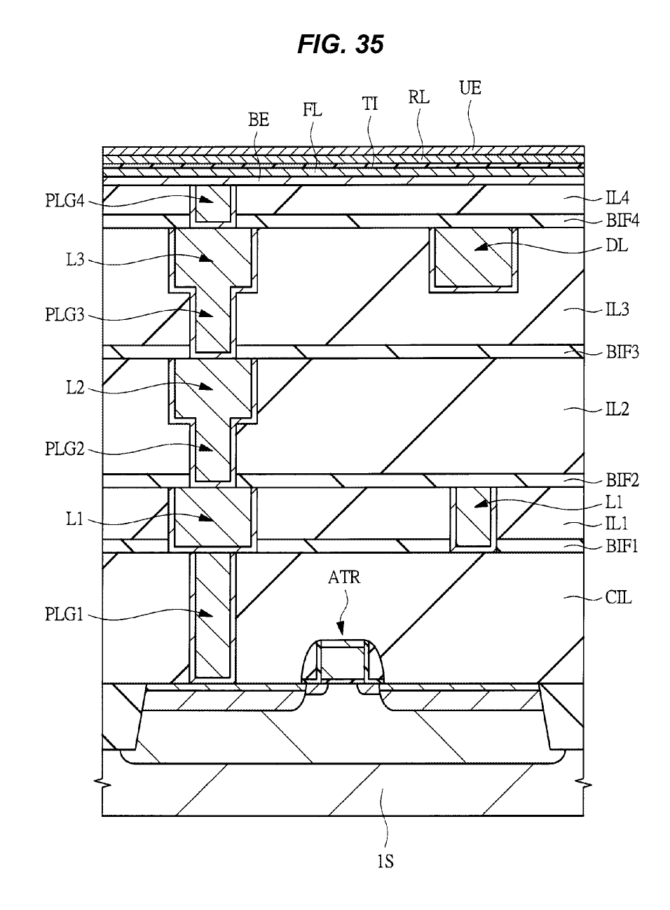

Then, as shown in FIG. 35, over the interlayer insulating film IL4 for which the plug PLG4 is formed, the bottom electrode BE is formed, and, over the bottom electrode BE, the fixed layer FL is formed. After that, over the fixed layer FL, the tunnel insulating film. TI is formed, and, over the tunnel insulating film TI, the recording layer RL is formed. Furthermore, over the recording layer RL, the upper electrode UE is formed.

The bottom electrode BE is formed from, for example, a film containing a tantalum film, a tantalum nitride film, a titanium film, a titanium nitride film, a ruthenium film, a nickel iron chromium (NiFeCr) film, or a laminated film thereof. The fixed layer FL is formed from a laminated film containing a nonmagnetic film, an antiferromagnetic film and a ferromagnetic film. On this occasion, the nonmagnetic layer is formed from such a metal film as a tantalum film, a ruthenium film, an aluminum film or a magnesium film. On the other hand, the antiferromagnetic layer is formed from, for example, a platinum manganese (PtMn) film, or an iridium manganese (IrMn) film. Furthermore, the ferromagnetic layer is formed so as to contain any of, for example, a nickel film, an iron film, a cobalt film and an alloy film containing an alloy of these films, and films formed by adding any of elements of chromium, molybdenum, aluminum, silicon, zirconium and boron to the nickel film, the iron film, the cobalt film or the alloy film.

Furthermore, the tunnel insulating film TI is formed from such a metal oxide film as, for example, an aluminum oxide film or a magnesium oxide film. On the other hand, the recording layer RL is formed so as to contain any of a nickel film, an iron film, a cobalt film and an alloy film containing an alloy of these films, and films formed by adding any of elements of chromium, molybdenum, aluminum, silicon, zirconium and boron to the nickel film, the iron film, the cobalt film or the alloy film. The upper electrode UE is formed from, for example, a tantalum film or a ruthenium film.

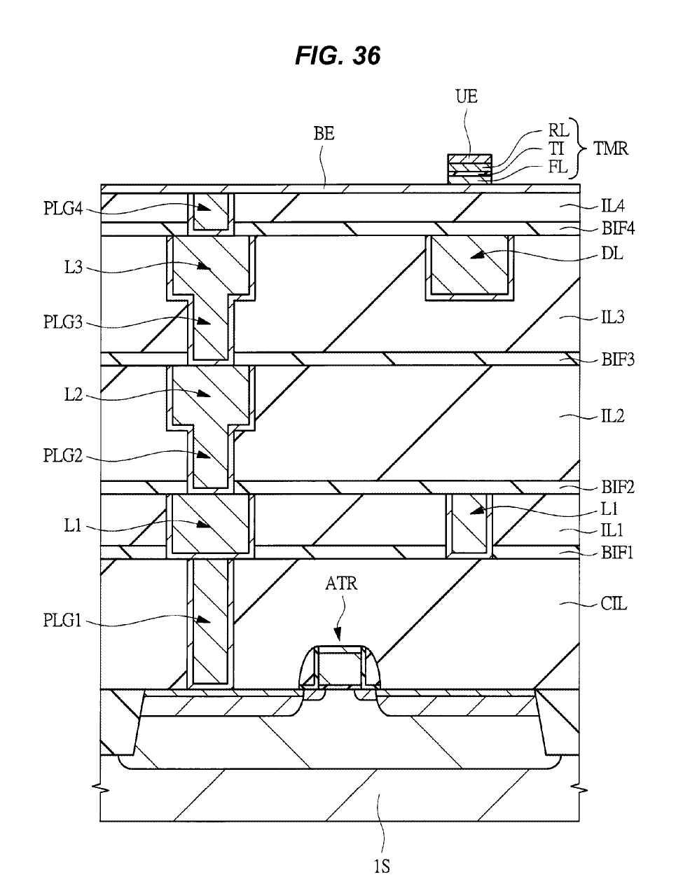

Subsequently, as shown in FIG. 36, the upper electrode UE, the recording layer RL, the tunnel insulating film TI and the fixed layer FL are patterned by using the photolithographic technology and the etching technology. This makes it possible to form the magneto resistance element TMR containing the recording layer RL, the tunnel insulating film TI and the fixed layer FL. The magneto resistance element TMR is formed so as to lie above the digit line DL.

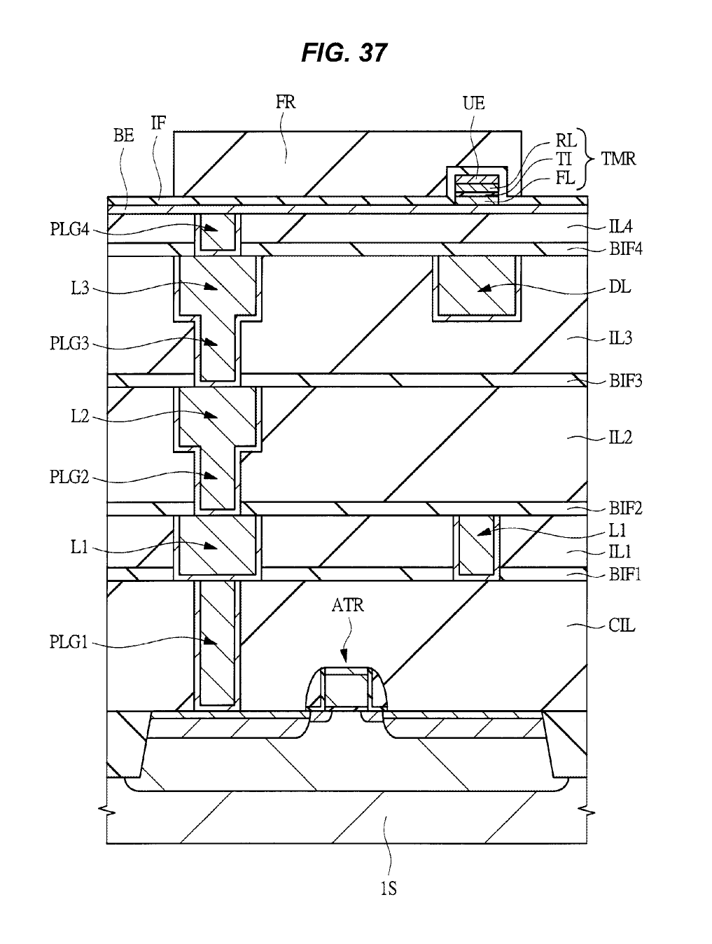

Next, as shown in FIG. 37, over the bottom electrode BE for which the magneto resistance element TMR is formed, the insulating film IF is formed, and, over the insulating film IF, a resist film FR is formed. Then, the resist film FR is subjected to an exposure/development treatment to be patterned. The resist film FR is patterned so as to remain in a region where the bottom electrode BE is to be left.

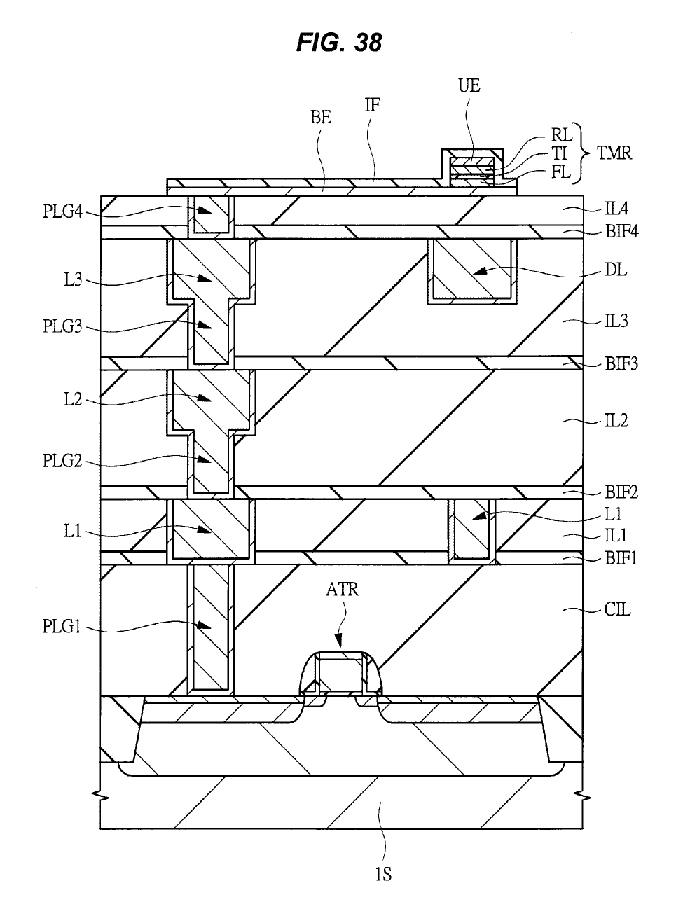

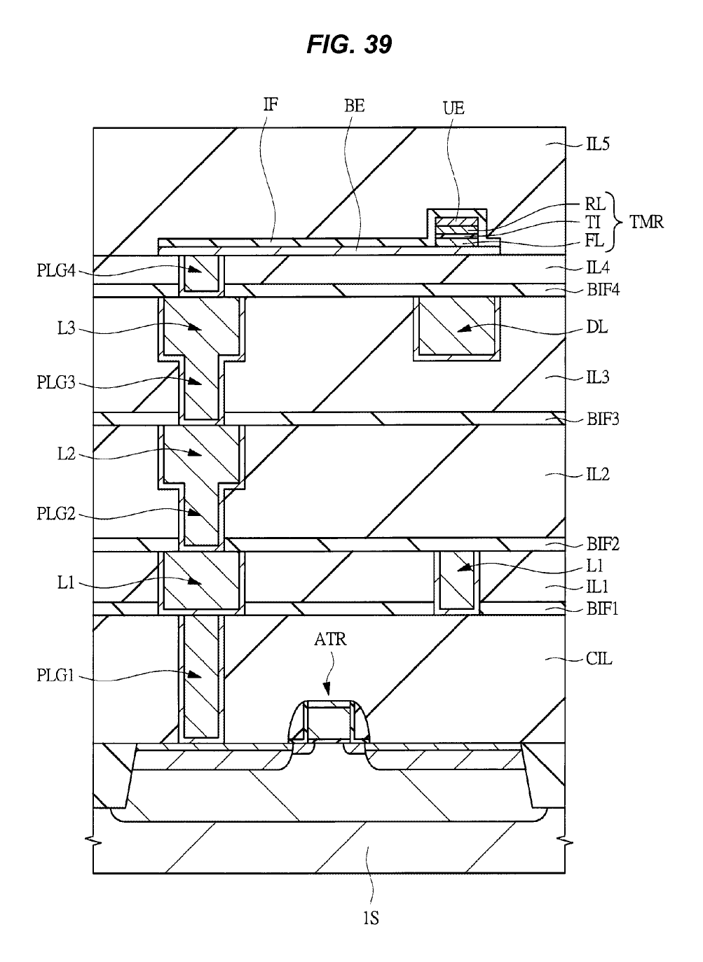

Then, as shown in FIG. 38, the insulating film IF and the bottom electrode BE are processed by etching using the patterned resist film FR as a mask. After that, as shown in FIG. 39, over the interlayer insulating film IL4 for which the magneto resistance element TMR is formed, the interlayer insulating film IL5 is formed. The interlayer insulating film IL5 is formed, for example, from a silicon oxide film.

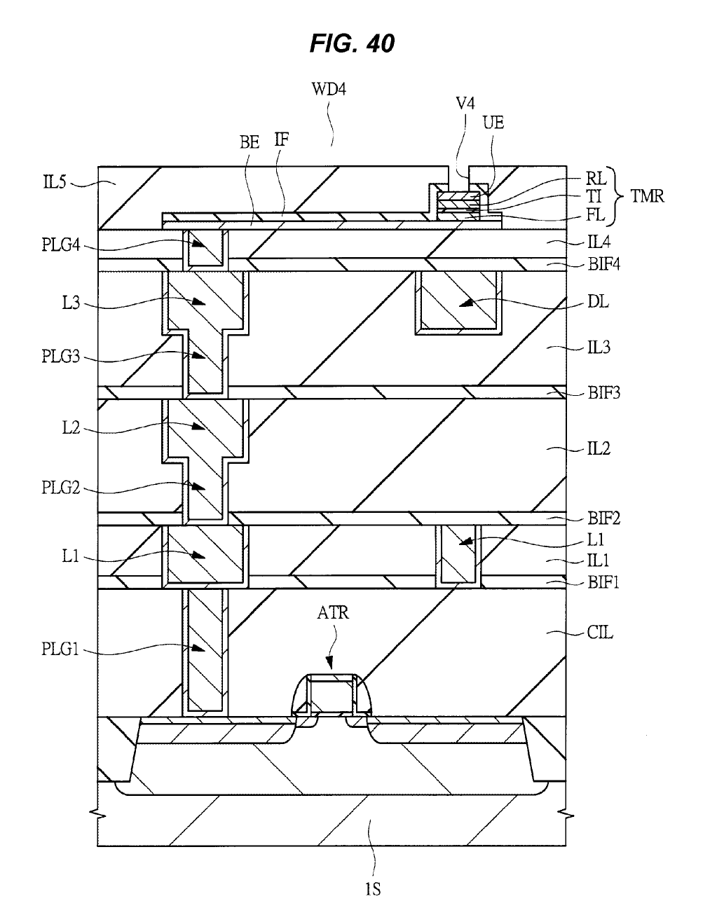

Subsequently, as shown in FIG. 40, for the interlayer insulating film IL5, the wiring trench WD4 and the via hole V4 are formed by using the photolithographic technology and the etching technology. On this occasion, the via hole V4 is formed so as to pass through the interlayer insulating film IL5 and the insulating film IF to expose the upper electrode UE of the magneto resistance element TMR.

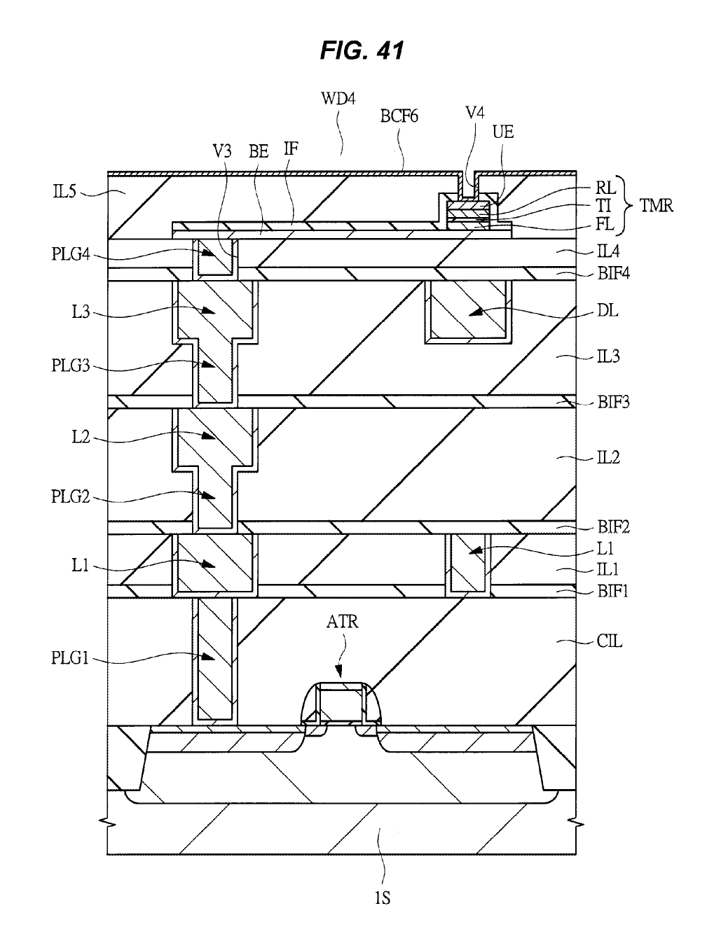

Next, as shown in FIG. 41, over the interlayer insulating film IL5 for which the wiring trench WD4 and the via hole V4 are formed, the barrier conductor film BCF6 is formed. Specifically, the constitution of the barrier conductor film BCF6 differs from that of the barrier conductor film BCF2 and the barrier conductor film BCF3 that constitute a part of the wiring L2 and a part of the wiring L1 described above. That is, the barrier conductor film BCF6 is formed so as to contain a ferromagnetic film having a high permeability. For example, the barrier conductor film BCF6 is formed from a laminated film containing a tantalum nitride film, a first tantalum film formed over the tantalum nitride film, a ferromagnetic film formed over the first tantalum film, and a second tantalum film formed over the ferromagnetic film. However, films constituting the barrier conductor film BCF6 other than the ferromagnetic film may be formed from a tantalum film, a titanium film, a ruthenium film, a tungsten film, a manganese film, or a film containing any of nitride films and nitriding silicide films thereof.

The ferromagnetic film contained in the barrier conductor film BCF6 is formed so as to contain any of, for example, a nickel film, an iron film, a cobalt film, an alloy film containing an alloy of these films, and films formed by adding any of elements of chromium, molybdenum, aluminum, silicon, zirconium and boron to the nickel film, the iron film, the cobalt film or the alloy film.

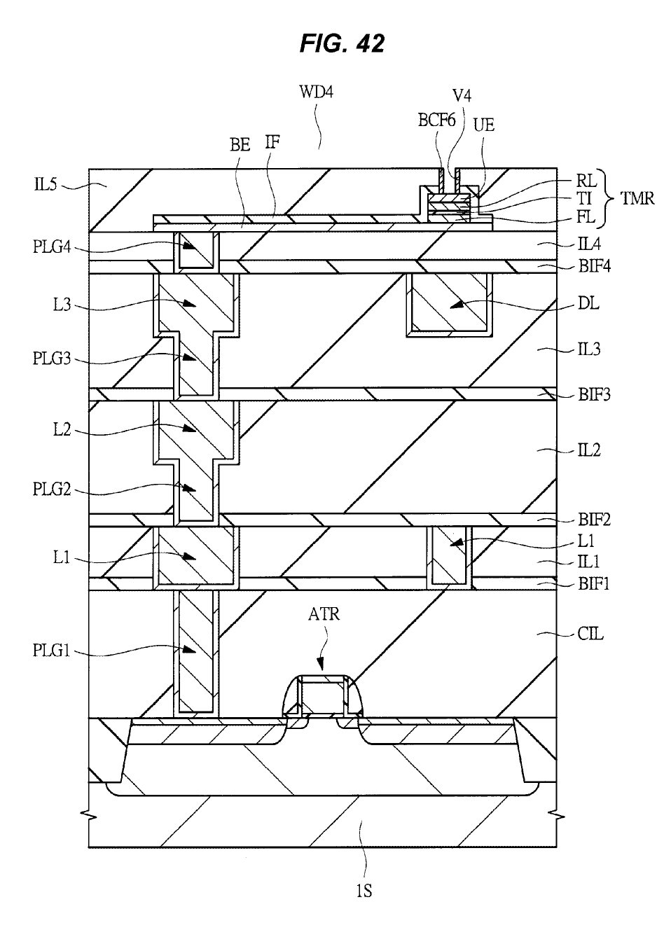

After that, as shown in FIG. 42, a part of the barrier conductor film BCF6 formed over the bottom surface of the wiring trench WD4 and the bottom surface of the via hole V4 is removed by a sputter etching method using argon. Specifically, the ferromagnetic film and the second tantalum film are removed. Consequently, the ferromagnetic film and the second tantalum film are formed only on the side wall of the wiring trench WD4 and the side wall of the via hole V4, and, on the bottom surface of the wiring trench WD4 and the side wall of the via hole V4, the tantalum nitride film and the first tantalum film are left.

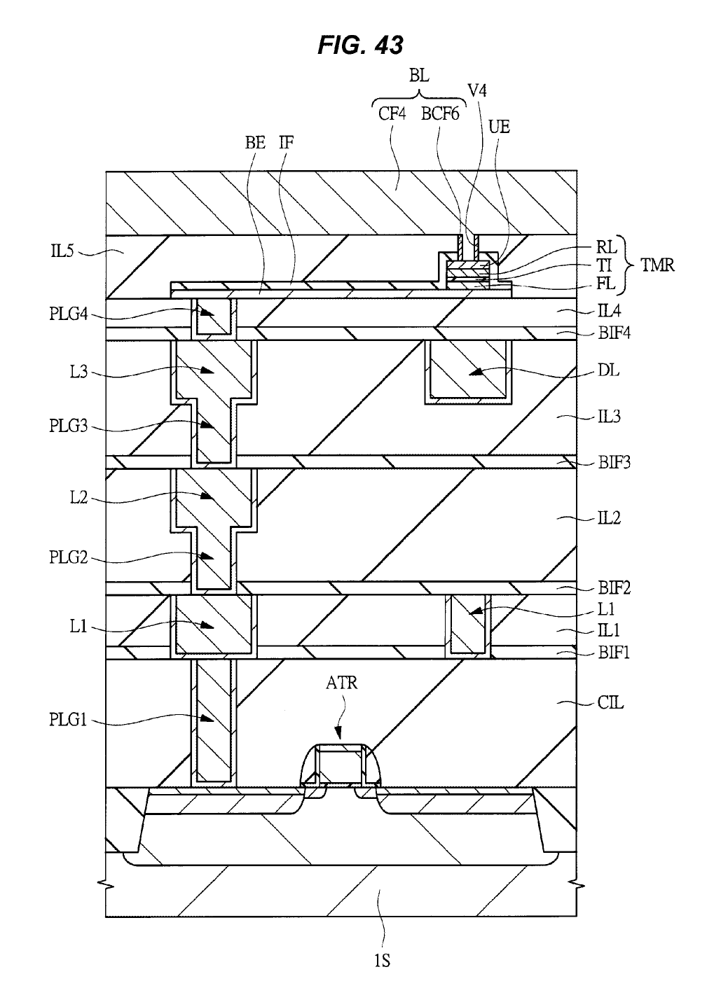

Subsequently, as shown in FIG. 43, over the barrier conductor film BCF6 and the interlayer insulating film IL5 formed on the wiring trench WD4 and the side surface of the via hole V4, for example, a seed film containing a thin copper film is formed by a sputtering method. Then, by an electrolytic plating method using the seed film as an electrode, the copper film CF4 is formed. The copper film CF4 is formed so as to be embedded into the wiring trench WD4 and the via hole V4. The copper film CF4 is formed from, for example, a film containing copper as the main constituent. Specifically, it is formed from copper (Cu) or a copper alloy (an alloy of copper (Cu) with aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), indium (In), lanthanoid-based metal or actinoid-based metal).

Next, an unnecessary copper film CF4 formed over the interlayer insulating film IL5 is removed by the CMP method. Consequently, the bit line BL containing the copper film CF4 and the barrier conductor film BCF6 may be formed. After that, as shown in FIG. 3, the clad film CLD1 is formed over the copper film CF4 constituting the bit line BL to make it possible to form the bit line BL containing the barrier conductor film BCF6, the copper film CF4 and the clad film CLD1. The clad film CLD1 contains, for example, a film containing a ferromagnetic film. In the Embodiment 1, since the barrier conductor film BCF6 and the clad film CLD1 constituting the bit line BL have a constitution containing a ferromagnetic film, the cladding structure is given to the bit wiring BL. As described above, the semiconductor device in the Embodiment 1 may be manufactured.

Meanwhile, as described above, prior to the deposition of the barrier insulating films BIF2 to BIF4, surfaces of wirings L1 to L3 are subjected to a plasma treatment, wherein these plasma treatments are performed with the apparatus for depositing the barrier insulating films BIF2 to BIF4. Because, if the surface of the wiring is exposed to the air between the plasma treatment and the deposition process of the barrier insulating films BIF2 to BIF4, copper lying on the surface of the wiring is corroded by moisture or oxidized by oxygen.

The barrier conductor film BCF4 contains a ferromagnetic material. Accordingly, if an apparatus used for depositing the barrier insulating film BIF4 is also used for depositing the barrier insulating films BIF2 and BIF3, there occurs a problem of contamination by the ferromagnetic material when depositing the barrier insulating films BIF2 and BIF3.

Furthermore, for solving the aforementioned problem of the hillock, the treatment is designed to be carried out under such a condition that the film forming temperature of the barrier insulating film BIF4 (for example, around 280° C. that is the same in the preceding plasma treatment) is lower than the film forming temperature of the barrier insulating films BIF2 and BIF3 (for example, around 400° C. that is the same in the preceding plasma treatment). This suppresses the heat supplied to the wiring L3 to suppress the hillock. Accordingly, the apparatus for depositing the barrier insulating films BIF2 and BIF3 at least differs from the apparatus for depositing the barrier insulating film BIF4, and the apparatuses operate differently.

For example, when the plasma treatment before the deposition of the barrier insulating films BIF2 and BIF3 is carried out under similar conditions as those in the plasma treatment before the deposition of the barrier insulating film BIF4, since it is necessary to preset the conditions in the plasma treatment for different apparatuses, the tuning requires time to increase the development cost and period. Therefore, by separating the conditions of the plasma treatment before the deposition of the barrier insulating films BIF2 and BIF3 from the conditions of the plasma treatment before the deposition of the barrier insulating film BIF4, as to the plasma treatment before the deposition of the barrier insulating films BIF2 and BIF3, it becomes possible to use conditions following conventional conditions to shorten the tuning period. Furthermore, the apparatus for depositing the barrier insulating films BIF2 and BIF3 may also be used for manufacturing semiconductor devices not containing the MRAM.

### Embodiment 2

In the embodiment 1, as shown in FIG. 3, the example, in which the barrier insulating film BIF4 and the interlayer insulating film IL4 are formed over the digit line DL and the magneto resistance element TMR is formed over the interlayer insulating film IL4, is explained. In the Embodiment 2, an example, in which the barrier insulating film BIF4 is formed over the digit line DL and the magneto resistance element TMR (including the bottom electrode BE) is formed directly on the barrier insulating film BIF4, is explained.

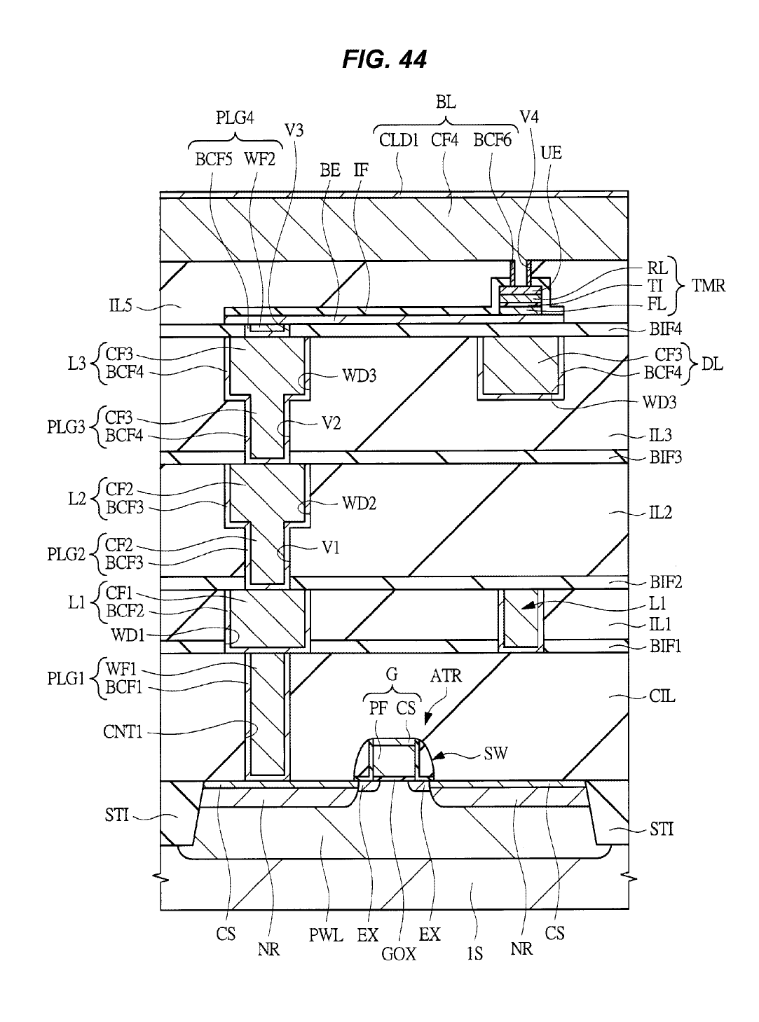

FIG. 44 is a cross-sectional view showing the structure of the semiconductor device in the Embodiment 2. FIG. 3 showing the structure of the semiconductor device in the embodiment 1 and FIG. 44 showing the structure of the semiconductor device in the Embodiment 2 are approximately the same. The difference lies in that, in FIG. 44, the barrier insulating film BIF4 is formed over the digit line DL, and that the magneto resistance element TMR (including the bottom electrode BE) is formed directly on the barrier insulating film BIF4.

The characteristic of the present invention lies in, for example, that the surface of the interlayer insulating film IL3 for which the wiring L3 and the digit line DL are formed is subjected to a plasma treatment. Specifically, the semiconductor substrate 1S is carried in a chamber, and a mixed gas including molecules containing nitrogen and inert molecules not containing nitrogen is introduced into the chamber. On this occasion, the mixed gas is introduced under such a condition that the flow rate of the inert molecules not containing nitrogen is larger than that of the molecules containing nitrogen, and the mixed gas is turned into plasma to perform the plasma treatment.

The plasma treatment may suppress the occurrence of the cavity defect caused by the hillock to make it possible to secure the flatness over the digit line DL. Consequently, the interval between the digit line DL and the magneto resistance element may be reduced.

Therefore, in the Embodiment 2, over the digit line DL, the barrier insulating film BIF4 is formed, and, on the barrier insulating film BIF4, the magneto resistance element TMR (including the bottom electrode BE) is formed directly without forming the interlayer insulating film IL4. According to the semiconductor device in the Embodiment 2 constituted as described above, the interval between the digit line DL and the magneto resistance element TMR may further be reduced as compared with the embodiment 1 to give an effect of reducing further the writing current caused to flow through the digit line DL.

Meanwhile, the method of manufacturing a semiconductor device in the Embodiment 2 is substantially the same as the method of manufacturing a semiconductor device in the embodiment 1, except for the point that the interlayer insulating film IL4 is not formed. Therefore, the explanation thereof is omitted.

Heretofore, inventions achieved by the present inventors have specifically been explained on the basis of the embodiment thereof. Needless to say, however, the present invention is not restricted to the embodiments, but may be changed variously in the range that does not deviate from the gist thereof.

The present invention may widely be utilized in manufacturing industries that manufacture semiconductor devices.

What is claimed is:

1. A method of manufacturing a semiconductor device, comprising the steps of:
(a) forming a MISFET over a semiconductor substrate,
(b) forming a first interlayer insulating film above the MISFET,
(c) forming a first trench in the first interlayer insulating film,
(d) forming a first barrier conductor film covering the side surface and the bottom surface of the first trench, forming a copper film containing copper as the main constituent over the first barrier conductor film so as to be embedded into the first trench, and thereby forming a first wiring in the first trench,
(e) performing a first plasma treatment on the surface of the first wiring and the surface of the first interlayer insulating film using a first gas that includes molecules containing nitrogen,
(f), after the step (e), forming a first copper diffusion-preventing film for suppressing diffusion of copper over the first wiring and the first interlayer insulating film,
(g) forming a second interlayer insulating film over the first copper diffusion-preventing film,
(h) forming a second trench in the second interlayer insulating film,
(i) forming a second barrier conductor film containing a ferromagnetic film so as to cover the side surface and the bottom surface of the second trench, forming a copper film containing copper as the main constituent over the second barrier conductor film so as to be embedded into the second trench, and thereby forming a second wiring in the second trench,
(j) performing a second plasma treatment on the surface of the second wiring and the surface of the second interlayer insulating film under such conditions that a second gas which includes molecules containing nitrogen and inert molecules not containing nitrogen is used and the flow rate of the inert molecules not containing nitrogen is larger than that of the molecules containing nitrogen,
(k), after the step (j), forming a second copper diffusion-preventing film for suppressing diffusion of copper over the second wiring and the second interlayer insulating film,
(l) forming a third interlayer insulating film over the second interlayer insulating film, and
(m) forming a magneto resistance element over the third interlayer insulating film,
wherein the second wiring is a wiring having a function of generating a part of the magnetic field for rewriting the information stored in the magneto resistance element by causing a current to flow through the second wiring.

2. The method of manufacturing a semiconductor device according to claim 1,
wherein the inert molecules not including nitrogen contained in the second gas include any of hydrogen gas, helium gas, and argon gas.

3. The method of manufacturing a semiconductor device according to claim 2,
wherein the molecules including nitrogen contained in the first gas are ammonia gas.

4. The method of manufacturing a semiconductor device according to claim 3,
wherein, in the step (j), the flow rate of the molecules including nitrogen relative to the flow rate of the inert molecules not including nitrogen is 2% or less.

5. The method of manufacturing a semiconductor device according to claim 2,
wherein the inside temperature of a chamber when the second plasma treatment is performed is lower than that of the chamber when the first plasma treatment is performed.

6. The method of manufacturing a semiconductor device according to claim 2,
wherein the time for performing the second plasma treatment is shorter than that for performing the first plasma treatment.

7. The method of manufacturing a semiconductor device according to claim 1,
wherein the second barrier conductor film is formed from a tantalum nitride film formed over the side surface and the bottom surface of the second trench, a first tantalum film formed over the tantalum nitride film, the ferromagnetic film formed over the first tantalum film, and a second tantalum film formed over the ferromagnetic film.

8. The method of manufacturing a semiconductor device according to claim 7,
wherein the ferromagnetic film is formed so as to contain any of a nickel film, an iron film, a cobalt film, an alloy film containing an alloy of these films, and a film formed by adding any element of chromium, molybdenum, aluminum, silicon, zirconium and boron to the nickel film, the iron film, the cobalt film or the alloy film.

9. The method of manufacturing a semiconductor device according to claim 8,
wherein the first barrier conductor film is formed from a tantalum film, a titanium film, a ruthenium film, a tungsten film, a manganese film, or a film containing any of a nitride film and a nitriding silicide film thereof.

10. The method of manufacturing a semiconductor device according to claim 9,
wherein the first copper diffusion-preventing film and the second copper diffusion-preventing film are formed from a film containing any of a SiN film, a SiON film, a SiC film, a SiCN film and a SiCO film.

11. The method of manufacturing a semiconductor device according to claim 10,
wherein the first interlayer insulating film and the second interlayer insulating film are formed so as to contain any of a SiOC film, an HSQ film, an MSQ film, a TEOS film, a silicon oxide film and a SiOF film.

12. A method of manufacturing a semiconductor device, comprising the steps of:
(a) forming a MISFET over a semiconductor substrate,
(b) forming a first interlayer insulating film above the MISFET,
(c) forming a first trench in the first interlayer insulating film,
(d) forming a first barrier conductor film covering the side surface and the bottom surface of the first trench, forming a copper film containing copper as the main constituent over the first barrier conductor film so as to be embedded into the first trench, and thereby forming a first wiring in the first trench,
(e) performing a first plasma treatment on the surface of the first wiring and the surface of the first interlayer insulating film using a first gas that includes molecules containing nitrogen,
(f), after the step (e), forming a first copper diffusion-preventing film for suppressing diffusion of copper over the first wiring and the first interlayer insulating film,
(g) forming a second interlayer insulating film over the first copper diffusion-preventing film,
(h) forming a second trench in the second interlayer insulating film,
(i) forming a second barrier conductor film containing a ferromagnetic film so as to cover the side surface and the bottom surface of the second trench, forming a copper film containing copper as the main constituent over the second barrier conductor film so as to be embedded into the second trench, and thereby forming a second wiring in the second trench,
(j) performing a second plasma treatment on the surface of the second wiring and the surface of the second interlayer insulating film using a second gas that includes molecules containing nitrogen and inert molecules not containing nitrogen,
(k), after the step (j), forming a second copper diffusion-preventing film for suppressing diffusion of copper over the second wiring and the second interlayer insulating film, and
(l) forming a magneto resistance element over the second copper diffusion-preventing film so as to directly contact the film,
wherein the second wiring is a wiring having a function of generating a part of the magnetic field for rewriting the information stored in the magneto resistance element by causing a current to flow through the second wiring.

13. The method of manufacturing a semiconductor device according to claim 12,
wherein the inert molecules not including nitrogen constituting the second gas are hydrogen gas.

14. A method of manufacturing a semiconductor device having a magneto resistance element for storing information, and a cladding for generating a part of a magnetic field for rewriting the information stored in the magneto resistance element by causing a current to flow, the method comprising the steps of:
(a) forming an interlayer insulating film above a semiconductor substrate,
(b) forming a trench in the interlayer insulating film,
(c) forming a barrier conductor film covering the side surface and the bottom surface of the trench and containing a ferromagnetic film, forming a copper film containing copper as the main constituent over the barrier conductor film so as to be embedded into the trench, and thereby forming the cladding in the trench,
(d) performing a plasma treatment on the surface of the cladding and the surface of the interlayer insulating film under such conditions that a gas which includes molecules containing nitrogen and inert molecules not containing nitrogen is used and the flow rate of the inert molecules not containing nitrogen is larger than that of the molecules containing nitrogen,
(e), after the step (d), forming a copper diffusion-preventing film for suppressing diffusion of copper over the cladding and the interlayer insulating film, and
(f) forming the magneto resistance element above the copper diffusion-preventing film.

15. The method of manufacturing a semiconductor device according to claim 14,
wherein the inert molecules not including nitrogen contained in the gas include any of hydrogen gas, helium gas, and argon gas.

16. The method of manufacturing a semiconductor device according to claim 15,
wherein the flow rate of the molecules containing nitrogen relative to the flow rate of the inert molecules not containing nitrogen is 2% or less.

17. A method of manufacturing a semiconductor device, comprising the steps of:
(a) forming a MISFET over a semiconductor substrate,
(b) forming a first interlayer insulating film above the MISFET,
(c) forming a first trench in the first interlayer insulating film,
(d) forming a first barrier conductor film covering the side surface and the bottom surface of the first trench, forming a copper film containing copper as the main constituent so as to be embedded into the first trench over the first barrier conductor film, and thereby forming a first wiring in the first trench,
(e) performing a first plasma treatment on the surface of the first wiring and the surface of the first interlayer insulating film using a first gas including molecules containing nitrogen,
(f), after the step (e), forming a first copper diffusion-preventing film for suppressing diffusion of copper over the first wiring and the first interlayer insulating film,
(g) forming a second interlayer insulating film over the first copper diffusion-preventing film,
(h) forming a second trench in the second interlayer insulating film,
(i) forming a second barrier conductor film containing a ferromagnetic film so as to cover the side surface and the bottom surface of the second trench, forming a copper film containing copper as the main constituent over the second barrier conductor film so as to be embedded into the second trench, and thereby forming a second wiring in the second trench,
(j) performing a second plasma treatment on the surface of the second wiring and the surface of the second interlayer insulating film under such conditions that a second gas which includes molecules containing nitrogen and inert molecules not containing nitrogen is used and the flow rate of the inert molecules not containing nitrogen is larger than that of the molecules containing nitrogen,
(k), after the step (j), forming a second copper diffusion-preventing film for suppressing diffusion of copper over the second wiring and the second interlayer insulating film, and
(l) forming a magneto resistance element on the second copper diffusion-preventing film so as to directly contact the film,
wherein the second wiring is a wiring having a function of generating a part of the magnetic field for rewriting the information stored in the magneto resistance element by causing a current to flow through the second wiring.

18. The method of manufacturing a semiconductor device according to claim 17,
wherein the inert molecules not including nitrogen contained in the second gas include any of hydrogen gas, helium gas, and argon gas.

19. The method of manufacturing a semiconductor device according to claim 18,
wherein the molecules including nitrogen contained in the first gas are ammonia gas.

20. The method of manufacturing a semiconductor device according to claim 19,
wherein, in the step (j), the flow rate of the molecule containing nitrogen relative to the flow rate of the inert molecules not containing nitrogen is 2% or less.

21. A semiconductor device comprising:
(a) an interlayer insulating film having a trench formed above a semiconductor substrate,
(b) a magneto resistance element for storing information,
(c) a cladding that has a function of generating apart of a magnetic field for rewriting the information stored in the magneto resistance element by causing a current to flow and is constituted so that a barrier conductor film containing a ferromagnetic film and a copper film containing copper as the main constituent are embedded in the trench formed in the interlayer insulating film, and
(d) a copper diffusion-preventing film formed over the cladding,
wherein the magneto resistance element is formed on the copper diffusion-preventing film so as to directly contact the film.

22. The semiconductor device according to claim 21,
wherein the magneto resistance element includes:
(b1) a bottom electrode formed over the copper diffusion-preventing film so as to directly contact the film,
(b2) a fixed layer that is formed over the bottom electrode and has a fixed direction of magnetization,
(b3) a tunnel insulating film formed over the fixed layer, and
(b4) a recording layer that is formed over the tunnel insulating film and has a variable direction of magnetization, and
wherein the magneto resistance element stores information by utilizing that a resistance value when the direction of magnetization of the fixed layer and the direction of magnetization of the recording layer are in parallel differs from a resistance value when the direction of magnetization of the fixed layer and the direction of magnetization of the recording layer are in antiparallel.

23. The semiconductor device according to claim 22,
wherein the barrier conductor film is formed from a tantalum nitride film formed over the side surface and the bottom surface of the trench, a first tantalum film formed over the tantalum nitride film, the ferromagnetic film formed over the first tantalum film, and a second tantalum film formed over the ferromagnetic film.

24. The semiconductor device according to claim 23,
wherein the ferromagnetic film is formed so as to contain any of a nickel film, an iron film, a cobalt film, an alloy film containing an alloy of these films, and a film formed by adding any element of chromium, molybdenum, aluminum, silicon, zirconium and boron to the nickel film, the iron film, the cobalt film or the alloy film.

25. The semiconductor device according to claim 24,
wherein the copper diffusion-preventing film is formed from a film containing any of a SiN film, a SiON film, a SiC film, a SiCN film, and a SiCO film.

26. The semiconductor device according to claim 25,
wherein the interlayer insulating film is formed so as to contain any of a SiOC film, an HSQ film, an MSQ film, a TEOS film, a silicon oxide film, and a SiOF film.
